(19) United States
(12) Patent Application Publication
(10) Pub. No.: US 2025/0160009 A1
(43) Pub. Date: May 15, 2025

(54) SOLID-STATE IMAGING DEVICE AND ELECTRONIC APPARATUS

(71) Applicant: SONY SEMICONDUCTOR SOLUTIONS CORPORATION, KANAGAWA (JP)

(72) Inventor: HISAO YOSHIMURA, KANAGAWA (JP)

(21) Appl. No.: 18/835,899

(22) PCT Filed: Jan. 30, 2023
(86) PCT No.: PCT/JP2023/002803

§ 371 Date: Aug. 5, 2024

(30) Foreign Application Priority Data
Feb. 15, 2022 (JP) 2022-021186

(51) Int. Cl. H10F 39/00; H10F 39/18

(52) U.S. Cl. CPC H10F 39/80373; H10F 39/014; H10F 39/18; H10F 39/802; H10F 39/8063

(57) ABSTRACT

The present disclosure relates to a solid-state imaging device and an electronic apparatus capable of suppressing an increase in gate capacitance of a transfer transistor having a vertical gate electrode structure. The solid-state imaging device includes a photoelectric conversion region formed in a semiconductor substrate, the semiconductor substrate having a first surface and a second surface with different heights formed adjacent to a wiring layer, a floating diffusion region formed on an opposite side of the semiconductor substrate from the photoelectric conversion region relative to the first surface and between the first surface and the second surface, and a transfer transistor that transfers charges generated in the photoelectric conversion region to the floating diffusion region, in which the transfer transistor has a vertical gate electrode structure in which a gate electrode is formed on a side surface connecting the first surface and the second surface. The present disclosure can be applied to, for example, a solid-state imaging device and the like.

### TECHNICAL FIELD

The present disclosure relates to a solid-state imaging device and an electronic apparatus, and more particularly, to a solid-state imaging device and an electronic apparatus capable of suppressing an increase in gate capacitance of a transfer transistor having a vertical gate electrode structure.

### BACKGROUND ART

A CMOS image sensor has a configuration in which pixels that convert an optical signal into an electrical signal are arranged in an array of several thousand rows and several thousand columns. Each pixel is provided with a transfer transistor, and charges generated by photoelectrical conversion in a photodiode are transferred to a floating diffusion region by the transfer transistor.

There has been a case where the vertical gate electrode structure is applied to a transfer transistor for the purpose of reducing a pixel size and increasing readout performance from a photodiode to a floating diffusion region. For example, Patent Document 1 discloses a technology to increase readout performance by enclosing a floating diffusion region with a vertical gate electrode structure in which a gate electrode of a transfer transistor is buried in a silicon substrate.

The transfer transistor using the vertical gate electrode structure can make a gate length long enough even if the pixel size is small, and therefore has an advantage in that a gate electrode's capability to modulate potential within a pixel can be maintained.

### CITATION LIST

### Patent Document

Patent Document 1: Japanese Patent Application Laid-Open No. 2012-164971

### SUMMARY OF THE INVENTION

### Problems to be Solved by the Invention

The trench gate electrode structure disclosed in Patent Document 1, however, makes a surface area of a gate electrode in contact with a silicon region with a gate insulating film interposed therebetween larger. For example, as illustrated in FIG. 6D of Patent Document 1, a surface area of a gate electrode structure in which a circular trench gate electrode having a diameter of 0.1 microns is buried to a depth of 0.5 microns is about 0.16 square microns, which is about three times as large as a gate area of a typical 0.8-micron pixel. Therefore, the gate capacitance per pixel increases.

In a CMOS image sensor, when a signal of each pixel is read, transfer transistors of a plurality of pixels in the same row is driven simultaneously, so that when the gate capacitance per pixel increases, an RC delay time at the time of readout increases, which becomes a constraint on high-speed readout.

The present disclosure has been made in view of such circumstances, and it is therefore an object of the present disclosure to suppress an increase in gate capacitance of a transfer transistor having a vertical gate electrode structure.

### Solutions to Problems

A solid-state imaging device according to a first aspect of the present disclosure includes:
a photoelectric conversion region formed in a semiconductor substrate, the semiconductor substrate having a first surface and a second surface with different heights formed adjacent to a wiring layer;
a floating diffusion region formed on an opposite side of the semiconductor substrate from the photoelectric conversion region relative to the first surface and between the first surface and the second surface; and
a transfer transistor that transfers charges generated in the photoelectric conversion region to the floating diffusion region, in which
the transfer transistor has a vertical gate electrode structure in which a gate electrode is formed on a side surface connecting the first surface and the second surface.

An electronic apparatus according to a second aspect of the present disclosure includes
a solid-state imaging device, the solid-state imaging device including:
a photoelectric conversion region formed in a semiconductor substrate, the semiconductor substrate having a first surface and a second surface with different heights formed adjacent to a wiring layer;
a floating diffusion region formed on an opposite side of the semiconductor substrate from the photoelectric conversion region relative to the first surface and between the first surface and the second surface; and
a transfer transistor that transfers charges generated in the photoelectric conversion region to the floating diffusion region, in which
the transfer transistor has a vertical gate electrode structure in which a gate electrode is formed on a side surface connecting the first surface and the second surface.

In the first and second aspects of the present disclosure, a photoelectric conversion region formed in a semiconductor substrate, the semiconductor substrate having a first surface and a second surface with different heights formed adjacent to a wiring layer, a floating diffusion region formed on an opposite side of the semiconductor substrate from the photoelectric conversion region relative to the first surface and between the first surface and the second surface, and a transfer transistor that transfers charges generated in the photoelectric conversion region to the floating diffusion region are provided, and the transfer transistor has a vertical gate electrode structure in which a gate electrode is formed on a side surface connecting the first surface and the second surface.

The solid-state imaging device and the electronic apparatus may be each an independent device or a module incorporated in another device.

### BRIEF DESCRIPTION OF DRAWINGS

FIG. 1 is a diagram illustrating a schematic configuration of a solid-state imaging device according to an embodiment of the present disclosure.

FIG. 2 is a diagram illustrating a circuit configuration example of each pixel two-dimensionally arranged in a matrix in a pixel array unit.

FIG. 3 is a plan view and a cross-sectional view of a first structure example of the pixel.

FIG. 4 is a diagram for describing effects produced by a transfer transistor in FIG. 3.

FIG. 5 is a diagram for describing a method for manufacturing the pixel according to the first structure example.

FIG. 6 is a diagram for describing the method for manufacturing the pixel according to the first structure example.

FIG. 7 is a diagram for describing the method for manufacturing the pixel according to the first structure example.

FIG. 8 is a diagram for describing the method for manufacturing the pixel according to the first structure example.

FIG. 9 is a diagram for describing the method for manufacturing the pixel according to the first structure example.

FIG. 10 is a diagram for describing the method for manufacturing the pixel according to the first structure example.

FIG. 11 is a diagram for describing the method for manufacturing the pixel according to the first structure example.

FIG. 12 is a plan view and a cross-sectional view of a second structure example of the pixel.

FIG. 13 is a diagram for describing a method for manufacturing the pixel according to the second structure example.

FIG. 14 is a diagram for describing the method for manufacturing the pixel according to the second structure example.

FIG. 15 is a diagram for describing the method for manufacturing the pixel according to the second structure example.

FIG. 16 is a diagram for describing the method for manufacturing the pixel according to the second structure example.

FIG. 17 is a diagram for describing the method for manufacturing the pixel according to the second structure example.

FIG. 18 is a plan view and a cross-sectional view of a third structure example of the pixel.

FIG. 19 is a diagram for describing a method for manufacturing the pixel according to the third structure example.

FIG. 20 is a diagram for describing the method for manufacturing the pixel according to the third structure example.

FIG. 21 is a diagram for describing the method for manufacturing the pixel according to the third structure example.

FIG. 22 is a diagram for describing the method for manufacturing the pixel according to the third structure example.

FIG. 23 is a diagram for describing the method for manufacturing the pixel according to the third structure example.

FIG. 24 is a diagram for describing the method for manufacturing the pixel according to the third structure example.

FIG. 25 is a diagram for describing the method for manufacturing the pixel according to the third structure example.

FIG. 26 is a plan view and a side view of a modification of the transfer transistor of the present disclosure.

FIG. 27 is a plan view of an example where the transfer transistor of the present disclosure is applied to a phase difference detection pixel.

FIG. 28 is a diagram for describing a usage example of an image sensor.

FIG. 29 is a block diagram illustrating a configuration example of an imaging device as an electronic apparatus to which the technology of the present disclosure is applied.

### MODE FOR CARRYING OUT THE INVENTION

Hereinafter, modes for carrying out the technology of the present disclosure (hereinafter, referred to as embodiments) will be described with reference to the accompanying drawings. The description will be given in the following order.
1. Schematic configuration example of solid-state imaging device
2. Circuit configuration example of pixel
3. First structure example of pixel
4. Method for manufacturing pixel according to first structure example
5. Second structure example of pixel
6. Method for manufacturing pixel according to second structure example
7. Third structure example of pixel
8. Method for manufacturing pixel according to third structure example
9. Modification of transfer transistor
10. Application example to phase difference detection pixel
11. Usage example of image sensor
12. Application example to electronic apparatus

Note that, in the drawings referred to in the following description, the same or similar parts are denoted by the same or similar reference signs, and redundant description will be omitted as appropriate. The drawings are schematic, and the relationship between the thickness and the plane dimension, the ratio of the thickness of each layer, and the like are different from the actual ones. Furthermore, the drawings may include portions having different dimensional relationships and ratios.

Furthermore, the definitions of directions such as up and down in the following description are merely definitions for convenience of description, and do not limit the technical idea of the present disclosure. For example, when an object is observed by rotating the object by 90°, the up and down are converted into and read as left and right, and when the object is observed by rotating the object by 180°, the up and down are inverted and read.

### 1. Schematic Configuration Example of Solid-State Imaging Device

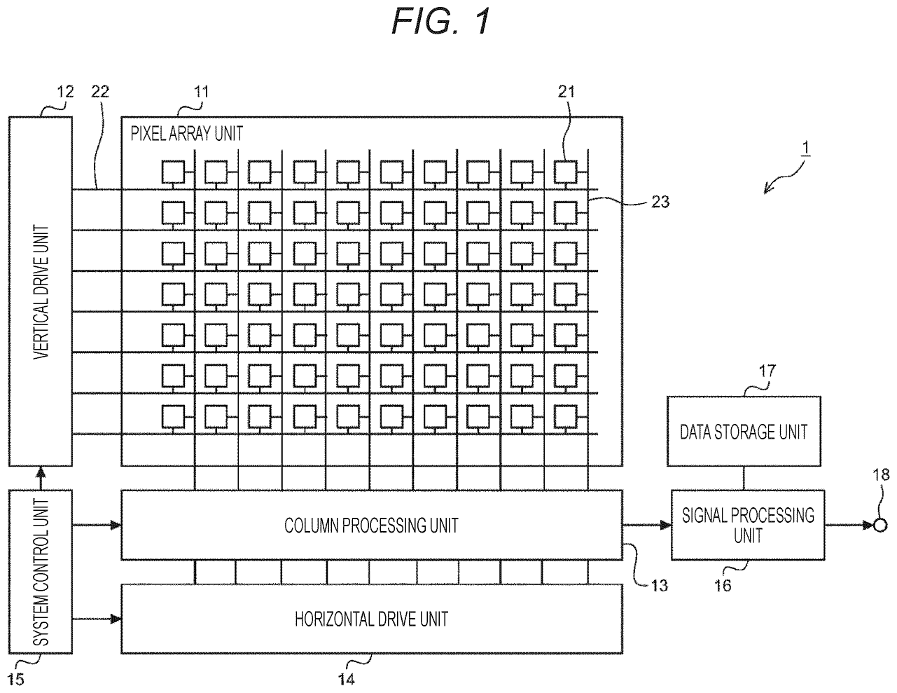

FIG. 1 is a diagram illustrating a schematic configuration of a solid-state imaging device according to an embodiment of the present disclosure.

A solid-state imaging device 1 in FIG. 1 illustrates a configuration of a CMOS image sensor which is a type of solid-state imaging device of an X-Y address system, for example. The CMOS image sensor is an image sensor manufactured by applying or partially using a CMOS process.

The solid-state imaging device 1 includes a pixel array unit 11 and a peripheral circuit unit. The peripheral circuit unit includes, for example, a vertical drive unit 12, a column processing unit 13, a horizontal drive unit 14, and a system control unit 15.

The solid-state imaging device 1 further includes a signal processing unit 16 and a data storage unit 17. The signal processing unit 16 and the data storage unit 17 may be mounted on the same substrate as the pixel array unit 11, the vertical drive unit 12, and the like, or may be arranged on another substrate. Furthermore, the signal processing unit 16 and the data storage unit 17 may be provided in a semiconductor chip different from the solid-state imaging device 1.

The pixel array unit 11 has a configuration in which a plurality of pixels 21 is two-dimensionally arranged in a matrix in a row direction and a column direction. Here, the row direction refers to a pixel row of the pixel array unit 11, that is, an array direction in the horizontal direction, and the column direction refers to a pixel column of the pixel array unit 11, that is, an array direction in the vertical direction.

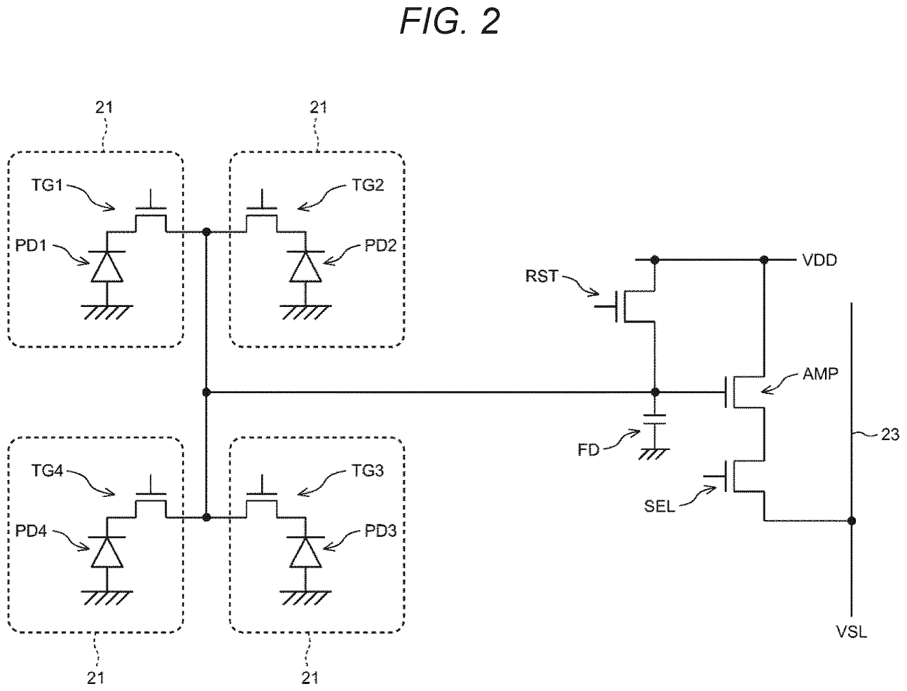

Each of the pixels 21 includes a photoelectric conversion unit that generates and accumulates charges corresponding to an amount of received light, and a plurality of pixel transistors (so-called MOS transistors). Note that a specific circuit configuration example of the pixel 21 will be described later with reference to FIG. 2 and the like.

Furthermore, in the pixel array unit 11, a pixel drive line 22 as a row signal line is wired along the row direction for each pixel row, and a vertical signal line 23 as a column signal line is wired along the column direction for each pixel column. The pixel drive line 22 transmits a drive signal for driving the pixel 21 to read a signal. Note that in FIG. 1, the pixel drive line 22 is illustrated as one line but is not limited to one. The pixel drive line 22 has one end connected to an output end corresponding to each row of the vertical drive unit 12.

The vertical drive unit 12 includes a shift register, an address decoder, and the like and drives each pixel of the pixel array unit 11 at the same time for all the pixels, in units of rows, or the like. The vertical drive unit 12 constitutes a drive unit that controls the operation of each pixel of the pixel array unit 11 together with the system control unit 15. Although a specific configuration of the vertical drive unit 12 is not illustrated, the vertical drive unit generally includes two scanning systems of a read scanning system and a sweep scanning system.

The read scanning system sequentially selects and scans the pixels 21 of the pixel array unit 11 row by row in order to read signals from the pixels 21. The signal read from each pixel 21 is an analog signal. The sweep scanning system performs sweep scanning on a read row on which the read scanning is to be performed by the read scanning system earlier than the read scanning by an exposure time.

By the sweep scanning by the sweep scanning system, unnecessary charges are swept out from the photoelectric conversion units of the pixels 21 in the read row, thereby resetting the photoelectric conversion units of each pixels 21. Then, when the unnecessary charges are swept out (reset) by the sweep scanning system, a so-called electronic shutter operation is performed. Here, the electronic shutter operation refers to operation of discharging the charges of the photoelectric conversion unit and newly starting exposure (starting accumulation of charges).

The signal read by the read operation of the read scanning system corresponds to the amount of light received after the immediately preceding read operation or electronic shutter operation. Then, a period from the read timing by the immediately preceding read operation or the sweep timing by the electronic shutter operation to the read timing by the current read operation is an exposure period in the pixel 21.

The signal output from each pixel 21 of the pixel row selectively scanned by the vertical drive unit 12 is input to the column processing unit 13 through each of the vertical signal lines 23 for each pixel column. The column processing unit 13 performs predetermined signal processing on the signal output from each pixel 21 of the selected row through the vertical signal line 23 for each pixel column of the pixel array unit 11, and temporarily holds the pixel signal after the signal processing.

Specifically, as the signal processing, the column processing unit 13 performs at least noise removal processing, for example, correlated double sampling (CDS). For example, in the CDS processing, pixel-specific fixed pattern noise, such as reset noise or threshold variation of an amplification transistor in each pixel, is removed. The column processing unit 13 may have, for example, a function of analog-digital (AD) conversion in addition to the noise removal processing and convert an analog pixel signal into a digital signal and output the digital signal.

The horizontal drive unit 14 includes a shift register, an address decoder, and the like, and sequentially selects a unit circuit corresponding to each pixel column in the column processing unit 13. When the selective scanning is performed by the horizontal drive unit 14, the pixel signal subjected to the signal processing for every unit circuit in the column processing unit 13 is sequentially output.

The system control unit 15 includes a timing generator that generates various timing signals and the like, and performs drive control of the vertical drive unit 12, the column processing unit 13, the horizontal drive unit 14, and the like on the basis of various timings generated by the timing generator.

The signal processing unit 16 has at least an arithmetic processing function, and performs various signal processing such as arithmetic processing on the pixel signal output from the column processing unit 13. The data storage unit 17 temporarily stores data necessary for the signal processing performed by the signal processing unit 16. The pixel signal subjected to the signal processing in the signal processing unit 16 is converted into a predetermined format and output from an output unit 18 to the outside of the device.

### 2. Circuit Configuration Example of Pixel

FIG. 2 illustrates a circuit configuration example of each of the pixels 21 two-dimensionally arranged in a matrix in the pixel array unit 11.

As illustrated in FIG. 2, for example, each pixel 21 has a shared pixel structure in which a readout circuit that reads a signal from each pixel is shared by four pixels in a two-by-two arrangement in the row direction and the column direction.

Specifically, in the pixel array unit 11, a photodiode PD and a transfer transistor TG as the photoelectric conversion unit are provided for each pixel, and a floating diffusion region FD, a reset transistor RST, an amplification transistor AMP, and a selection transistor SEL are used in a shared manner by the four pixels corresponding to a sharing unit. The pixel transistors such as the transfer transistor TG, the reset transistor RST, the amplification transistor AMP, and the selection transistor SEL each include an N-type MOS transistor (MOS FET), and constitute the readout circuit.

In the drawing, in order to distinguish between the photodiodes PD and the transfer transistors TG of the four pixels sharing the readout circuit, numbers 1 to 4 are added, such as photodiodes PD1 to PD4 and transfer transistors TG1 to TG4.

The photodiode PD generates and accumulates charges (signal charges) corresponding to the amount of received light. The photodiode PD has an anode terminal grounded and a cathode terminal connected to the floating diffusion region FD via the transfer transistor TG.

When the transfer transistor TG is turned on by a transfer drive signal supplied to its gate electrode, the transfer transistor TG reads the charges generated by the photodiode PD and transfers the charges to the floating diffusion region FD. The floating diffusion region FD holds the charges read from at least one of the four photodiodes PD.

When the reset transistor RST is turned on by a reset drive signal supplied to its gate electrode, the reset transistor RST discharges the charges accumulated in the floating diffusion region FD to its drain (power supply voltage VDD), thereby resetting the potential of the floating diffusion region FD.

The amplification transistor AMP outputs a signal corresponding to the potential of the floating diffusion region FD. That is, the amplification transistor AMP constitutes a source follower circuit with a load MOS transistor (not illustrated) as a constant current source connected via the vertical signal line 23, and a signal VSL indicating a level corresponding to the charges accumulated in the floating diffusion region FD is output from the amplification transistor AMP to the column processing unit 13 (FIG. 1) via the selection transistor SEL.

The selection transistor SEL is turned on when the corresponding sharing unit is selected by a selection drive signal supplied to a gate electrode of the selection transistor SEL to output the signal VSL generated in each pixel 21 belonging to the sharing unit to the column processing unit 13 via the vertical signal line 23. The transfer drive signal, the selection drive signal, and the reset drive signal are supplied from the vertical drive unit 12 via the pixel drive line 22 in FIG. 1.

As described above, the four pixels 21 in a two-by-two arrangement of the sharing unit use, in a sharing manner, the pixel transistors including the reset transistor RST, the amplification transistor AMP, and the selection transistor SEL.

For example, the solid-state imaging device 1 can appropriately select and perform the following driving according to an operation mode.

For example, a first operation mode allows the solid-state imaging device 1 to sequentially turn on the transfer transistors TG of the four pixels of the sharing unit on a pixel-by-pixel basis, transfer charges generated in the photodiode PD of one pixel to the floating diffusion region FD, and output the charges as the signal VSL to the column processing unit 13 via the vertical signal line 23.

For example, a second operation mode allows the solid-state imaging device 1 to turn on the transfer transistors TG of every two pixels adjacent to each other in the row direction or the column direction of the four pixels of the sharing unit, transfer charges generated in the photodiodes PD of the two pixels simultaneously to the floating diffusion region FD, and output the charges as the signal VSL to the column processing unit 13 via the vertical signal line 23.

For example, a third operation mode allows the solid-state imaging device 1 to turn on the transfer transistors TG of all the four pixels of the sharing unit simultaneously, transfer charges generated in the photodiodes PD of the four pixels simultaneously to the floating diffusion region FD, and output the charges as the signal VSL to the column processing unit 13 via the vertical signal line 23.

Note that the sharing unit in which each pixel 21 shares the readout circuit is not limited to four pixels. For example, a circuit configuration in which eight pixels in a four-by-two arrangement or two-by-four arrangement share the readout circuit may be employed.

### 3. First Structure Example of Pixel

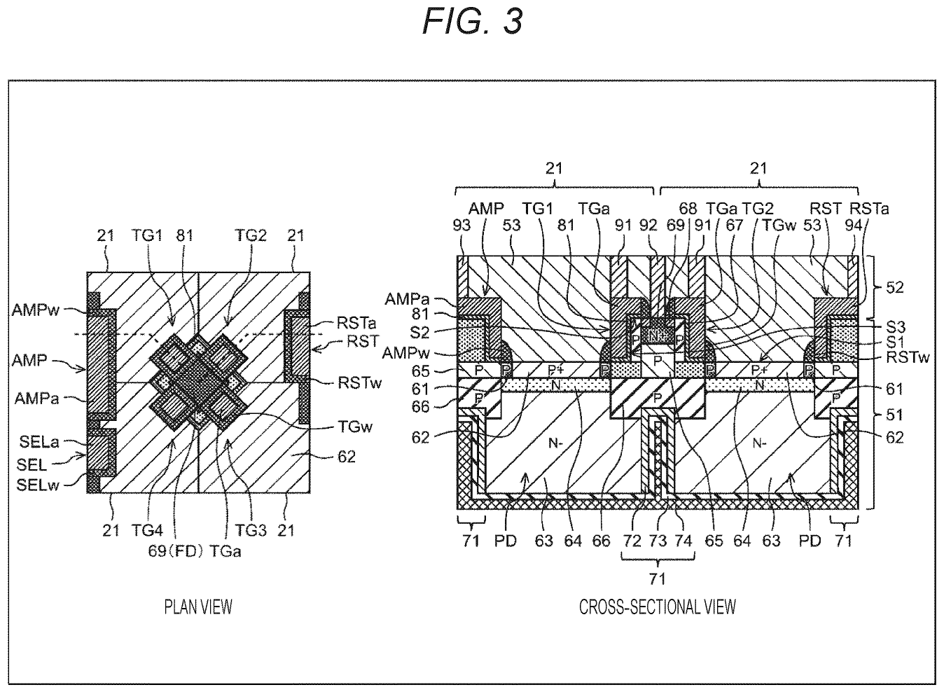

FIG. 3 is a plan view and a cross-sectional view of a first structure example of the pixel 21.

The left side of FIG. 3 illustrates a plan view of four pixel regions in a two-by-two arrangement constituting the sharing unit, and the right side of FIG. 3 illustrates a cross-sectional view taken along a line segment indicated by a dashed line in the plan view. The plan view is a plan view of a plane on which the pixel transistors have been formed.

As illustrated in the plan view, each pixel 21 has a rectangular region, and an N-type semiconductor region 69 constituting the floating diffusion region FD is arranged at the center portion of the four pixel regions constituting the sharing unit. The transfer transistors TG1 to TG4 of the pixels 21 are each arranged near the floating diffusion region FD in the corresponding pixel so as to surround the floating diffusion region FD. A gate electrode TGa of the transfer transistor TG is surrounded by a sidewall TGW.

The reset transistor RST, the amplification transistor AMP, and the selection transistor SEL, which are shared pixel transistors used in a shared manner by the four pixels constituting the sharing unit, are arranged at a pixel boundary portion of the four pixel regions constituting the sharing unit. More specifically, the reset transistor RST is arranged at a pixel boundary portion on the right side of the four pixel regions, and the amplification transistor AMP and the selection transistor SEL are arranged at a pixel boundary portion on the left side. Since the reset transistor RST, the amplification transistor AMP, and the selection transistor SEL are arranged at the pixel boundary portion that is a boundary with other left and right adjacent sharing units, such transistors are only partially illustrated. A gate electrode AMPa of the amplification transistor AMP is surrounded by a sidewall AMPw, and a gate electrode SELa of the selection transistor SEL is also surrounded by a sidewall SELw. A gate electrode RSTa of the reset transistor RST is also surrounded by a sidewall RSTW.

Note that, in the example in FIG. 3, the shared pixel transistors are arranged at the pixel boundary portion in the horizontal direction corresponding to the row direction of the pixel array unit 11, but the shared pixel transistors may be arranged at the pixel boundary portion in the vertical direction corresponding to the column direction of the pixel array unit 11.

In the following description, a region where the shared pixel transistor such as the reset transistor RST, the amplification transistor AMP, or the selection transistor SEL is arranged will be referred to as shared transistor region, and a region where the transfer transistor TG is arranged will be referred to as transfer transistor region.

As illustrated in the cross-sectional view on the right side of FIG. 3, each pixel 21 is formed in a semiconductor substrate 51 using a semiconductor material such as silicon (Si). On an upper surface of the semiconductor substrate 51 in the cross-sectional view, the pixel transistors such as the transfer transistor TG, the amplification transistor AMP, and the reset transistor RST, and a multilayer wiring layer 52 are formed. The multilayer wiring layer 52 is a layer including wiring (not illustrated) and an interlayer insulating film 53.

In the cross-sectional view, the upper surface of the semiconductor substrate 51 on which the multilayer wiring layer 52 is formed serves as a front surface of the semiconductor substrate 51, and a lower surface of the semiconductor substrate 51 serves as a back surface of the semiconductor substrate 51 and serves as a light incident surface on which light is incident. The front surface of the semiconductor substrate 51 has two surfaces having different heights, that is, a first surface S1 and a second surface S2 higher than the first surface S1. The lower surface is the first surface S1, and the higher surface is the second surface S2.

The transfer transistor TG, the reset transistor RST, the amplification transistor AMP, and the selection transistor SEL are each provided in a step portion between the first surface S1 and the second surface S2 adjacent to the front surface of the semiconductor substrate 51, and each have a vertical gate electrode structure in which the corresponding gate electrode is formed in a vertical direction orthogonal to a planar direction of the semiconductor substrate 51.

In the semiconductor substrate 51, P-type semiconductor regions 61 and 62 and N-type semiconductor regions 63 and 64 are formed for each pixel. The P-type semiconductor regions 61 and 62 and the N-type semiconductor regions 63 and 64 formed for each pixel constitute the photodiode PD using a PN junction, and serve as a photoelectric conversion region. The P-type semiconductor region 61 and the P-type semiconductor region 62 are different in impurity concentration from each other, and the P-type semiconductor region 62 is higher in concentration than the P-type semiconductor region 61. Similarly, the N-type semiconductor region 63 and the N-type semiconductor region 64 are different in impurity concentration from each other, and the N-type semiconductor region 64 is higher in concentration than the N-type semiconductor region 63.

Furthermore, a pixel trench portion 71 and P-type semiconductor regions 65 and 66 are formed as a pixel separation portion that partitions, into pixel units, the photoelectric conversion region formed for each pixel in the semiconductor substrate 51.

The pixel trench portion 71 is a groove portion that is formed by cutting into the semiconductor substrate 51 from the back surface side of the semiconductor substrate 51 to a predetermined depth and in which an insulating film 72, a fixed charge film 73, and an insulating film 74 are buried. The fixed charge film 73 and the insulating film 74 are further formed on an interface on the back surface side of the semiconductor substrate 51. The P-type semiconductor regions 65 and 66 are formed at a depth different from that of the pixel trench portion 71, specifically, between the pixel trench portion 71 and the first surface S1 adjacent to the front surface of the semiconductor substrate 51 to partition the photoelectric conversion region into pixel units.

The transfer transistor TG (TG1, TG2) includes the gate electrode TGa formed at the step portion between the first surface S1 and the second surface S2 of the semiconductor substrate 51 with a gate insulating film 81 interposed therebetween. The gate electrode TGa has a flipped L-shaped cross-sectional shape obtained by flipping an L-shape vertically, and a contact wiring 91 is connected to the gate electrode TGa. The sidewall TGW is formed around the gate electrode TGa. A P-type semiconductor region 67 in which a channel region of the transfer transistor TG is formed is formed in a region near a side surface S3 connecting the first surface S1 and the second surface S2 of the semiconductor substrate 51.

The N-type semiconductor region 69 as the floating diffusion region FD is formed in a center portion surrounded by the gate electrodes TGa of the transfer transistors TG1 to TG4, and a contact wiring 92 is connected to the N-type semiconductor region 69. An N-type semiconductor region 68 that is located under the sidewall TGw and is in contact with the N-type semiconductor region 69 is a lightly doped drain (LDD) region.

The amplification transistor AMP has the gate electrode AMPa on the side surface S3 connecting the first surface S1 and the second surface S2 of the semiconductor substrate 51 and the higher second surface S2 with the gate insulating film 81 interposed therebetween, and a contact wiring 93 is connected to the gate electrode AMPa. The sidewall AMPw is formed around the gate electrode AMPa.

The reset transistor RST has the gate electrode RSTa on the side surface S3 connecting the first surface S1 and the second surface S2 of the semiconductor substrate 51 and the higher second surface S2 via the gate insulating film 81 interposed therebetween, and a contact wiring 94 is connected to the gate electrode RSTa. The sidewall RSTw is formed around the gate electrode RSTa.

The pixel structure of the four pixel regions constituting the sharing unit is configured as described above.

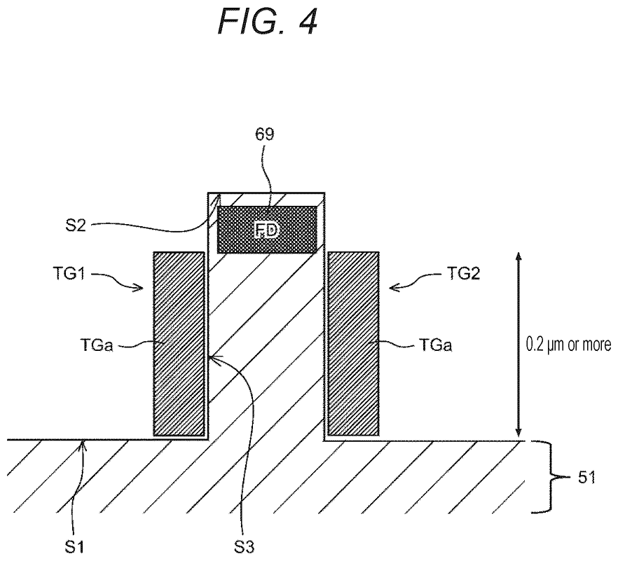

FIG. 4 is a diagram illustrating a simplified structure of the transfer transistor TG in FIG. 3.

The gate electrode TGa of the transfer transistor TG is formed on the side surface S3 that is formed adjacent to the multilayer wiring layer 52 of the semiconductor substrate 51 and connects the first surface S1 and the second surface S2 having different heights. The semiconductor substrate 51 is partially subjected to recess etching or selective epitaxial growth to form the first surface S1 and the second surface S2 of the semiconductor substrate 51. Then, the N-type semiconductor region 69 that is the floating diffusion region FD is formed in a semiconductor region on the opposite side of the semiconductor substrate 51 from the photodiode PD relative to the first surface S1 and between the first surface S1 and the second surface S2. The channel region of the transfer transistor TG is formed in a semiconductor region (P-type semiconductor region 67) on the side surface S3.

As described above, with the structure in which the floating diffusion region FD is formed at a position higher than the first surface S1 of the semiconductor substrate 51, that is, the floating diffusion region FD is lifted, the transfer transistor TG has a vertical gate electrode structure in which the gate electrode TGa is formed in the vertical direction along the side surface S3. The transfer transistor TG having the vertical gate electrode structure that suppresses an increase in gate capacitance by not burying the gate electrode TGa in the semiconductor substrate 51 is realized. Since there is no increase in gate capacitance, even in a case where the transfer transistors TG of a plurality of pixels in the same row is simultaneously driven, it is possible to reduce the RC delay time and achieve high-speed readout. Furthermore, even in a case where the pixel size is reduced, it is possible to make an effective gate length L of the transfer transistor TG long enough by providing the step between the first surface S1 and the second surface S2, and maintain the modulation characteristics of the transfer transistor TG. The height of the gate electrode TGa formed on the side surface S3 is preferably greater than or equal to 0.2 μm.

The solid-state imaging device 1 has the vertical gate electrode structure in which the floating diffusion region FD is lifted applied to the transfer transistor TG, so that it is possible to realize a transfer transistor that is small in gate capacitance and excellent in transfer characteristics. Even in a case where the pixel 21 is reduced in size, the transfer characteristics can be enhanced, and the readout speed can be increased even if the number of pixels of the pixel array unit 11 increases.

### 4. Method for Manufacturing Pixel According to First Structure Example

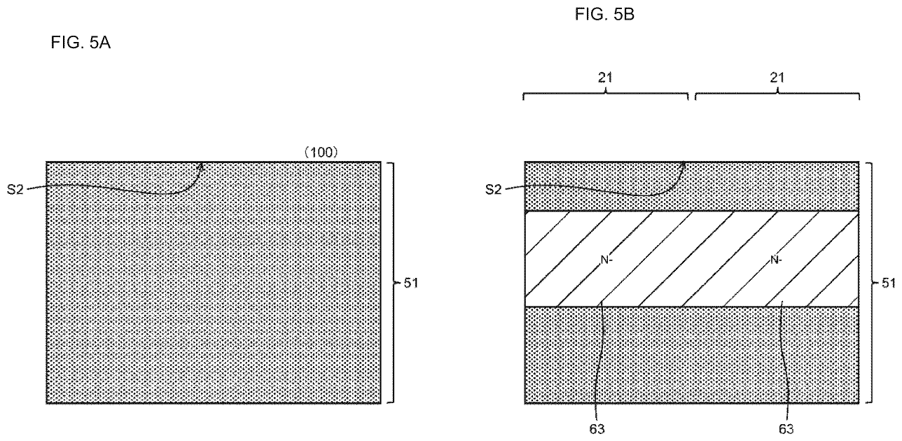

A method for manufacturing the pixel 21 according to the first structure example will be described with reference to FIGS. 5 to 11.

First, the semiconductor substrate 51 illustrated in A of FIG. 5 is prepared. The semiconductor substrate 51 is a substrate using a semiconductor material such as silicon (Si), for example. The upper surface of the semiconductor substrate 51 in A of FIG. 5 corresponds to the second surface S2 in a state where the pixel 21 is formed, and the plane orientation of the semiconductor substrate 51 is, for example, a (100) plane.

Next, as illustrated in B of FIG. 5, for example, N-type impurities such as phosphorus (P) are ion-implanted into a substrate region at a predetermined depth from the second surface S2 that is the front surface of the semiconductor substrate 51, and heat treatment (hereinafter, referred to as activation annealing treatment) for activation is further performed to form the N-type semiconductor region 63 having a low concentration. The N-type semiconductor region 63 is sandwiched between a substrate region adjacent to the front surface and a substrate region adjacent to the back surface.

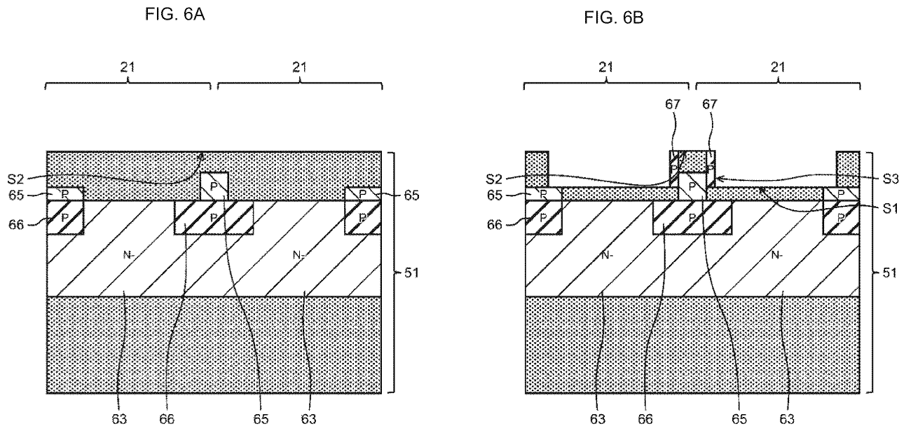

Next, as illustrated in A of FIG. 6, P-type impurities such as boron (B) are ion-implanted into the pixel boundary portion of the pixels 21 that partitions the pixel region into rectangular regions in a matrix, and activation annealing treatment is further performed to form the P-type semiconductor regions 65 and 66. The P-type semiconductor region 65 is formed in a substrate region on the interface between the substrate region adjacent to the front surface of the semiconductor substrate 51 and the N-type semiconductor region 63. The P-type semiconductor region 66 is formed in the N-type semiconductor region 63 under the interface between the substrate region adjacent to the front surface of the semiconductor substrate 51 and the N-type semiconductor region 63. As illustrated in A of FIG. 6, the P-type semiconductor region 65 of the transfer transistor region is formed from a depth position closer to the second surface S2 than the P-type semiconductor region 65 of the shared transistor region.

Next, as illustrated in B of FIG. 6, the substrate region on the N-type semiconductor region 63 is partially removed to a predetermined depth by recess etching using, for example, reactive ion etching (RIE). Specifically, a substrate region of the semiconductor substrate 51 other than the transfer transistor region and the shared transistor region is subjected to recess etching to form a recess in the semiconductor substrate 51 for each pixel. As a result, the first surface S1 obtained by cutting into the semiconductor substrate 51 by recess etching, the second surface S2 not etched, and the side surface S3 connecting the first surface S1 and the second surface S2 are formed on the front surface of the semiconductor substrate 51.

Moreover, as illustrated in B of FIG. 6, P-type impurities are ion-implanted into a portion to be the channel region of the transfer transistor TG, and activation annealing treatment is performed on the portion to form the P-type semiconductor region 67.

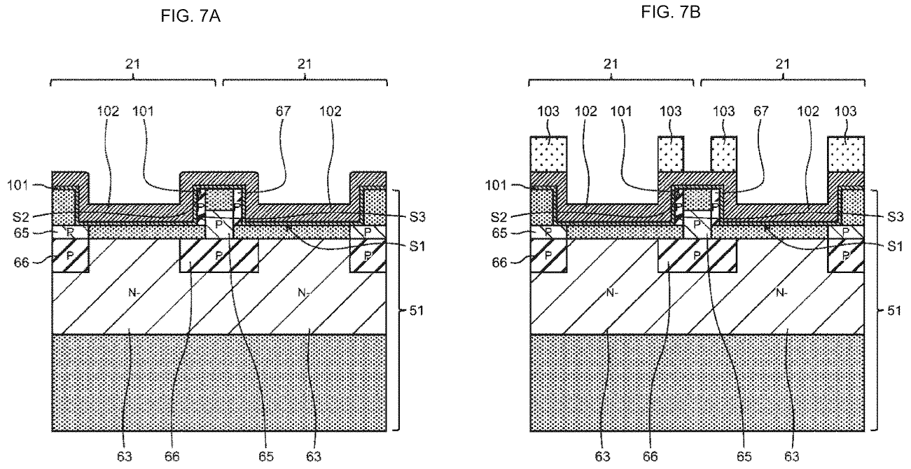

Next, as illustrated in A of FIG. 7, the surface of the semiconductor substrate 51 is subjected to oxidation treatment using, for example, ISSG to form an oxide film 101 to be used as the gate insulating film 81. Subsequently, a polysilicon layer 102 to be used as the gate electrode TGa and the like is formed on an upper surface of the oxide film 101 using, for example, LPCVD. The oxide film 101 has, for example, a thickness of about 6 nm, and the polysilicon layer 102 has, for example, a thickness of about 100 nm. Thereafter, for example, impurities such as phosphorus are introduced into the polysilicon layer 102 by ion implantation with about 3×10¹⁵ cm⁻² and an acceleration voltage of 5 KeV, and activation annealing treatment based on RTA is performed at 1000° C. for about 10 seconds to activate the impurities introduced into the polysilicon layer 102. As in A of FIG. 7, corners of the polysilicon layer 102 are rounded according to irregularities of the semiconductor substrate 51, but are illustrated as right-angled corners in the other drawings for the sake of simplicity.

Next, as illustrated in B of FIG. 7, a resist 103 is formed on an upper surface of the polysilicon layer 102, and is patterned by lithography according to the positions of the gate electrodes formed in the transfer transistor region and the shared transistor region.

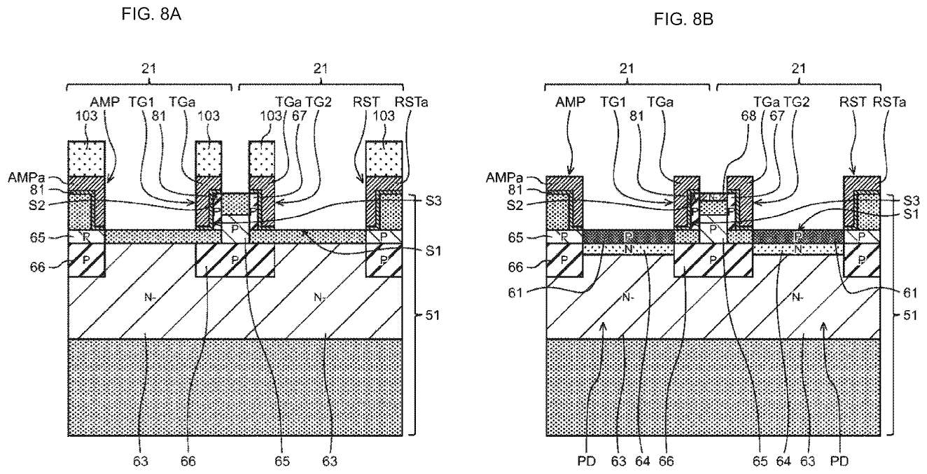

Then, as illustrated in A of FIG. 8, etching such as RIE is performed according to the patterned resist 103, so that the polysilicon layer 102 and the oxide film 101 other than the transistor regions are removed. Thereafter, the patterned resist 103 is removed. As a result, the gate electrode TGa and the gate insulating film 81 of the transfer transistor TG are formed in the transfer transistor region, and the gate electrode AMPa and the gate insulating film 81 of the amplification transistor AMP, the gate electrode RSTa and the gate insulating film 81 of the reset transistor RST, and the like are formed in the shared transistor region. Their respective gate electrodes of the transfer transistor region and the shared transistor region have a vertical gate electrode structure.

Next, as illustrated in B of FIG. 8, ion implantation of P-type impurities and N-type impurities and activation annealing treatment are sequentially performed on a portion near the interface of the first surface S1 of the semiconductor substrate 51 from which the polysilicon layer 102 and the oxide film 101 have been removed to form the P-type semiconductor region 61 and the N-type semiconductor region 64. The P-type semiconductor region 61 is formed in a layer near the interface of the first surface S1, and the N-type semiconductor region 64 is formed in a layer under the P-type semiconductor region 61.

Furthermore, ion implantation of N-type impurities and activation annealing treatment are performed on a substrate region surrounded by the gate electrodes TGa of the transfer transistors TG1 to TG4 to form the N-type semiconductor region 68 to be the LDD region.

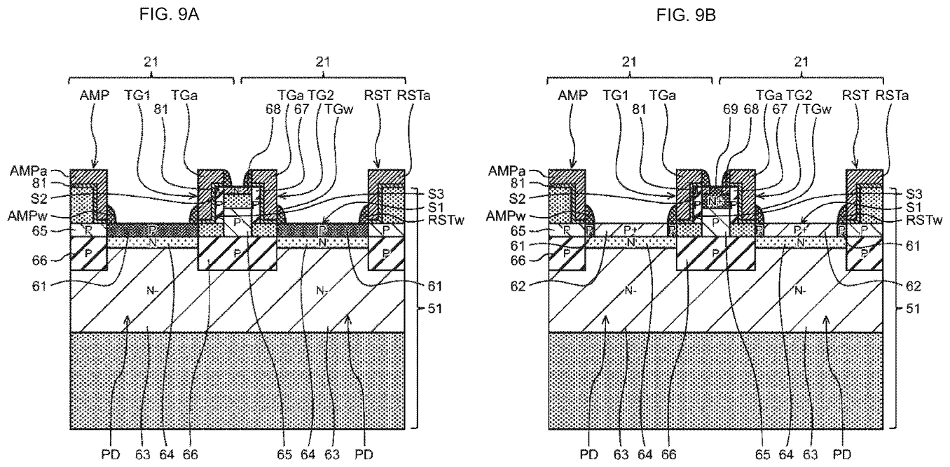

Next, as illustrated in A of FIG. 9, a sidewall of each pixel transistor is formed. That is, the sidewall TGw around the gate electrode TGa of the transfer transistor TG, the sidewall AMPw around the gate electrode AMPa of the amplification transistor AMP, the sidewall RSTw around the gate electrode RSTa of the reset transistor RST, and the sidewall SELw around the gate electrode SELa of the selection transistor SEL are formed (the selection transistor SEL is not illustrated). It is possible to form the sidewall of each pixel transistor by placing an oxide film, a nitride film, or the like on the upper surface of the semiconductor substrate 51 and then etching back the oxide film, the nitride film, or the like by RIE.

Next, as illustrated in B of FIG. 9, ion implantation of P-type impurities and activation annealing treatment are performed on the P-type semiconductor region 61 near the interface of the first surface S1 to form the P-type semiconductor region 62 for shielding the substrate surface. As a result, the P-type semiconductor region 62 becomes higher in impurity concentration than the P-type semiconductor region 61 under the sidewall of each pixel transistor.

Furthermore, ion implantation of N-type impurities and activation annealing treatment are performed on a substrate region surrounded by the gate electrodes TGa of the transfer transistors TG1 to TG4 to form the N-type semiconductor region 69 as the floating diffusion region FD. The N-type semiconductor region 69 becomes higher in impurity concentration than the N-type semiconductor region 68 of the LDD region.

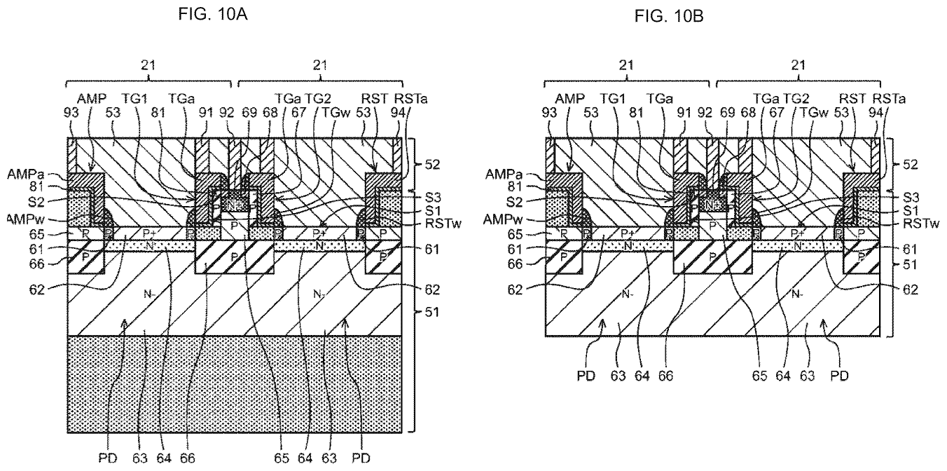

Next, as illustrated in A of FIG. 10, an oxide film or the like is formed in a layer on the semiconductor substrate 51 on which the pixel transistors have been formed by, for example, CVD or the like to be a part of the interlayer insulating film 53. Thereafter, a surface of the interlayer insulating film 53 is planarized using chemical mechanical polishing (CMP), and then a contact hole is formed at a position, corresponding to the contact wirings 91 to 94, of the interlayer insulating film 53 using, for example, RIE. Then, a barrier metal such as TiN/Ti is formed in the formed contact hole, and tungsten (W) is buried by CVD to form the contact wirings 91 to 94. Moreover, wiring (not illustrated) is further formed on the interlayer insulating film 53 using damascene or the like, thereby bringing the multilayer wiring layer 52 to completion.

After the semiconductor substrate 51 on which the multilayer wiring layer 52 and the pixel transistors have been formed is bonded to a logic substrate (not illustrated), as illustrated in B of FIG. 10, the back surface side of the semiconductor substrate 51, in other words, a side of the semiconductor substrate 51 remote from the surface bonded with the logic substrate is thinned until the N-type semiconductor region 63 is exposed.

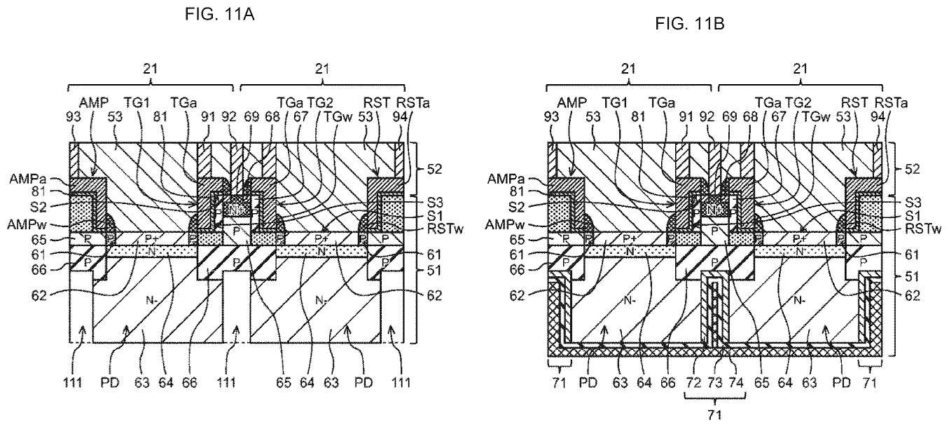

Next, as illustrated in A of FIG. 11, etching is performed on the back surface side of the semiconductor substrate 51 to form a groove portion 111 in the region to be the pixel trench portion 71. The groove portion 111 is formed to a depth that reaches the P-type semiconductor region 66.

Then, as illustrated in B of FIG. 11, the insulating film 72, the fixed charge film 73, and the insulating film 74 are buried, in this order, in the formed groove portion 111 to form the pixel trench portion 71. As the insulating film 72, for example, an oxide film of about 10 nm can be formed by ALD, and as the fixed charge film 73, for example, an oxide or nitride containing at least one element of hafnium (Hf), aluminum (Al), zirconium (Zr), tantalum (Ta), or titanium (Ti) can be formed. As the insulating film 74, for example, a silicon oxide (SiO₂), a silicon nitride (Si3N4), a silicon oxynitride (SiON), or the like can be formed. The fixed charge film 73 and the insulating film 74 are formed not only in the groove portion 111 but also on the whole of the back surface serving as the light incident surface of the semiconductor substrate 51.

As described above, the pixel 21 of the first structure example illustrated in FIG. 3 is manufactured. An antireflection film, a color filter layer, a microlens, and the like can be formed on the back surface side serving as the light incident surface of the semiconductor substrate 51, as necessary.

In the method for manufacturing the pixel 21 according to the first structure example described above, the step between the first surface S1 and the second surface S2 is formed by recess etching of the second surface S2 of the semiconductor substrate 51, but the step between the first surface S1 and the second surface S2 may be formed by selective epitaxial growth of a silicon layer on the first surface S1.

### 5. Second Structure Example of Pixel

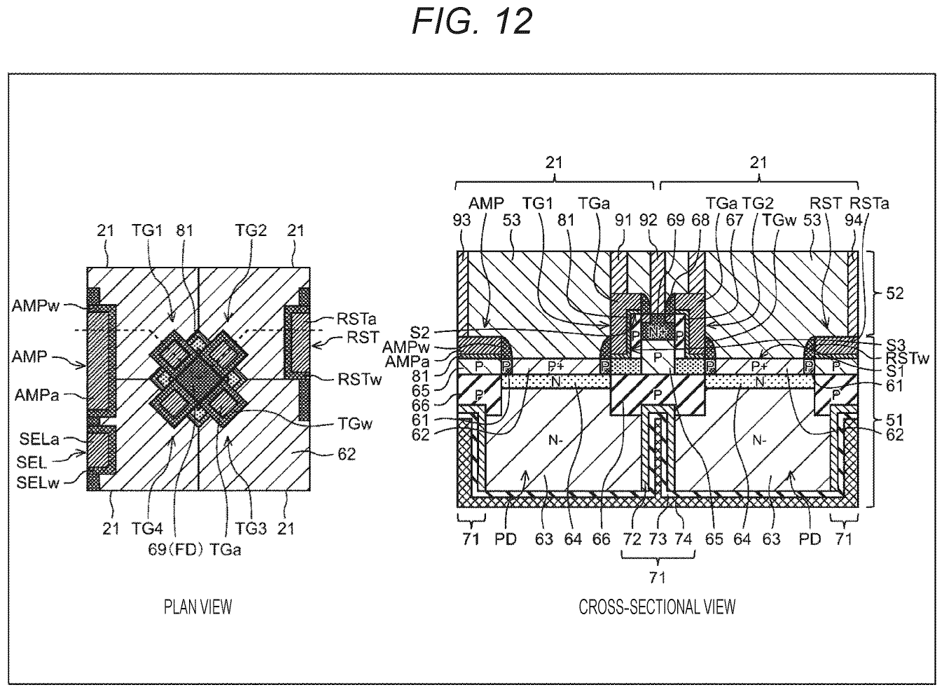

FIG. 12 is a plan view and a cross-sectional view illustrating a second structure example of the pixel 21.

In a manner similar to the first structure example illustrated in FIG. 3, FIG. 12 illustrates a plan view of four pixel regions in a two-by-two arrangement constituting a sharing unit and a cross-sectional view taken along a line segment indicated by a dashed line in the plan view.

In FIG. 12, parts corresponding to those in the first structure example illustrated in FIG. 3 are denoted by the same reference signs, description of those parts will be omitted as appropriate, and description will be given focusing on parts different from those in the first structure example.

In the first structure example illustrated in FIG. 3, the four transfer transistors TG1 to TG4 arranged in the center portion of the four pixel regions constituting the sharing unit, and the reset transistor RST, the amplification transistor AMP, and the selection transistor SEL arranged in the shared transistor region each include a vertical transistor having a vertical gate electrode structure in which a gate electrode is formed in the step portion between the first surface S1 and the second surface S2 of the semiconductor substrate 51.

On the other hand, in the second structure example in FIG. 12, the four transfer transistors TG1 to TG4 each include a vertical transistor having a vertical gate electrode structure in a manner similar to the first structure example, but the reset transistor RST, the amplification transistor AMP, and the selection transistor SEL in the shared transistor region each include a planar transistor having a planar gate electrode. Referring to the cross-sectional view, in the shared transistor region, there is no step portion between the first surface S1 and the second surface S2 of the semiconductor substrate 51, and the gate electrode AMPa of the amplification transistor AMP and the gate electrode RSTa of the reset transistor RST are formed on the first surface S1 of the semiconductor substrate 51 with the gate insulating film 81 interposed therebetween.

The second structure example in FIG. 12 is similar to the first structure example in FIG. 3 except that each pixel transistor in the shared transistor region includes a planar transistor instead of a vertical transistor.

Also in the second structure example, since the four transfer transistors TG1 to TG4 each include a vertical transistor having a vertical gate electrode structure in a manner similar to the first structure example, it is possible to realize a transfer transistor small in gate capacitance and excellent in transfer characteristics. Even in a case where the pixel 21 is reduced in size, the transfer characteristics can be enhanced, and the readout speed can be increased even if the number of pixels of the pixel array unit 11 increases.

### 6. Method for Manufacturing Pixel According to Second Structure Example

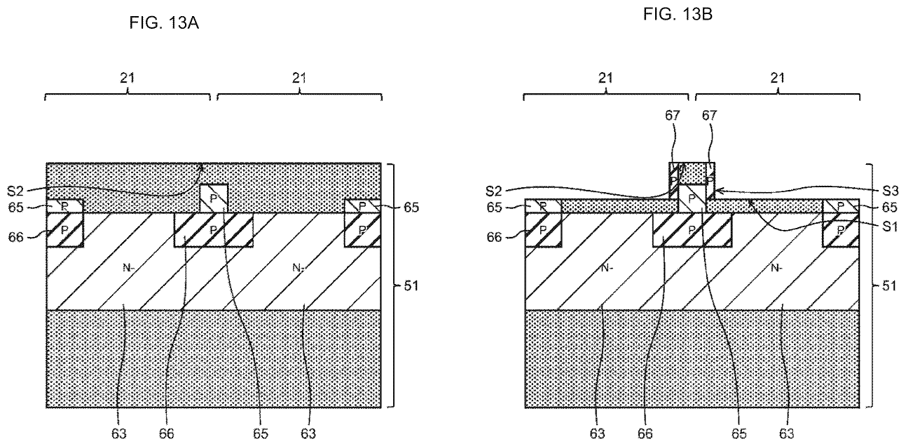

Next, a method for manufacturing the pixel 21 according to the second structure example will be described with reference to FIGS. 13 to 17.

A state illustrated in A of FIG. 13 is similar to the state in A of FIG. 6 described in the manufacturing method of the first structure example. Since the steps up to the state illustrated in A of FIG. 13 are similar to those of the first structure example described with reference to A and B of FIG. 5 and A of FIG. 6, description thereof will be omitted. Through the steps up to A of FIG. 13, the N-type semiconductor region 63 is formed at a predetermined depth of the semiconductor substrate 51, and the P-type semiconductor regions 65 and 66 are formed at the pixel boundary portion of the pixels 21 that partitions the pixel region into rectangular regions in a matrix.

Next, as illustrated in B of FIG. 13, the substrate region on the N-type semiconductor region 63 of the semiconductor substrate 51 other than the transfer transistor region is removed to a predetermined depth by recess etching using, for example, RIE. As a result, the second surface S2 is formed in the transfer transistor region of the semiconductor substrate 51, and the first surface S1 is formed in the other region. The step in B of FIG. 13 corresponds to the step in B of FIG. 6 of the first structure example.

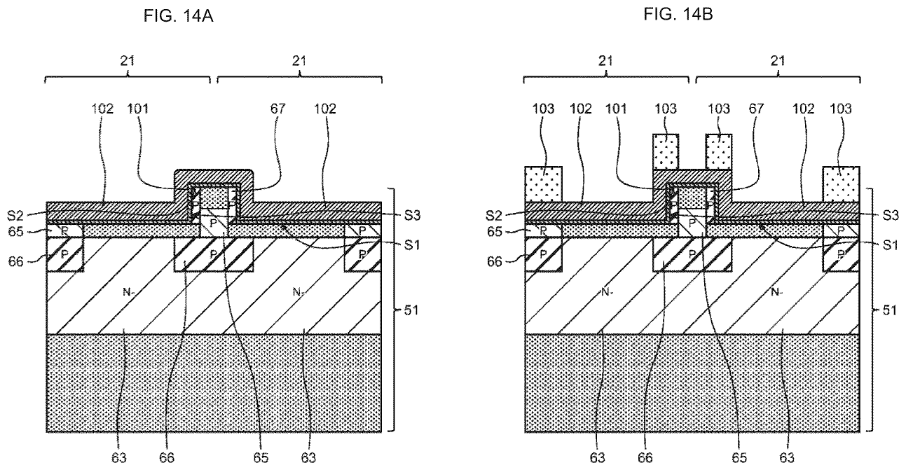

Next, as illustrated in A of FIG. 14, the surface of the semiconductor substrate 51 is subjected to oxidation treatment using, for example, ISSG to form the oxide film 101 to be used as the gate insulating film 81. Subsequently, the polysilicon layer 102 to be used as the gate electrode TGa and the like is formed on an upper surface of the oxide film 101 using, for example, LPCVD. The oxide film 101 has, for example, a thickness of about 6 nm, and the polysilicon layer 102 has, for example, a thickness of about 100 nm. For example, impurities such as phosphorus are introduced into the polysilicon layer 102 by ion implantation with about 3×10¹⁵ cm⁻² and an acceleration voltage of 5 KeV, and activation annealing treatment based on RTA is performed at 1000° C. for about 10 seconds to activate the impurities introduced into the polysilicon layer 102. As in A of FIG. 14, corners of the polysilicon layer 102 are rounded according to irregularities of the semiconductor substrate 51, but are illustrated as right-angled corners in the other drawings for the sake of simplicity. The step in A of FIG. 14 corresponds to the step in A of FIG. 7 of the first structure example.

Next, as illustrated in B of FIG. 14, the resist 103 is formed on an upper surface of the polysilicon layer 102, and is patterned by lithography according to the positions of the gate electrodes formed in the transfer transistor region and the shared transistor region. The step in B of FIG. 14 corresponds to the step in B of FIG. 7 of the first structure example.

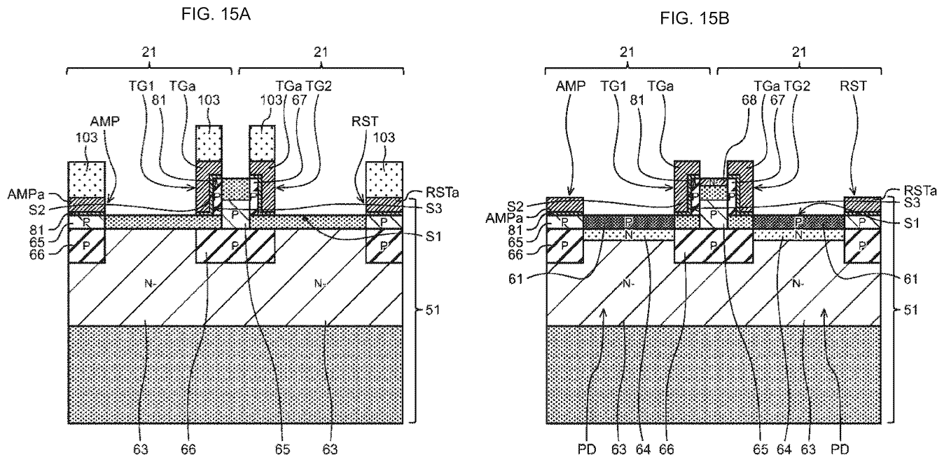

Next, as illustrated in A of FIG. 15, etching such as RIE is performed according to the patterned resist 103, so that the polysilicon layer 102 and the oxide film 101 other than the transistor regions are removed. Thereafter, the patterned resist 103 is removed. As a result, the gate electrode TGa and the gate insulating film 81 of the transfer transistor TG are formed in the transfer transistor region, and the gate electrode AMPa and the gate insulating film 81 of the amplification transistor AMP, the gate electrode RSTa and the gate insulating film 81 of the reset transistor RST, and the like are formed in the shared transistor region. The gate electrode TGa in the transfer transistor region has a vertical gate electrode structure, and the gate electrodes AMPa, RSTa, and the like in the shared transistor region have a planar gate electrode structure. The step in A of FIG. 15 corresponds to the step in A of FIG. 8 of the first structure example.

Next, as illustrated in B of FIG. 15, ion implantation of P-type impurities and N-type impurities and activation annealing treatment are sequentially performed on a portion near the interface of the first surface S1 of the semiconductor substrate 51 from which the polysilicon layer 102 and the oxide film 101 have been removed to form the P-type semiconductor region 61 and the N-type semiconductor region 64. The P-type semiconductor region 61 is formed in a layer near the interface of the first surface S1, and the N-type semiconductor region 64 is formed in a layer under the P-type semiconductor region 61.

Furthermore, ion implantation of N-type impurities and activation annealing treatment are performed on a substrate region surrounded by the gate electrodes TGa of the transfer transistors TG1 to TG4 to form the N-type semiconductor region 68 to be the LDD region. The step in B of FIG. 15 corresponds to the step in B of FIG. 8 of the first structure example.

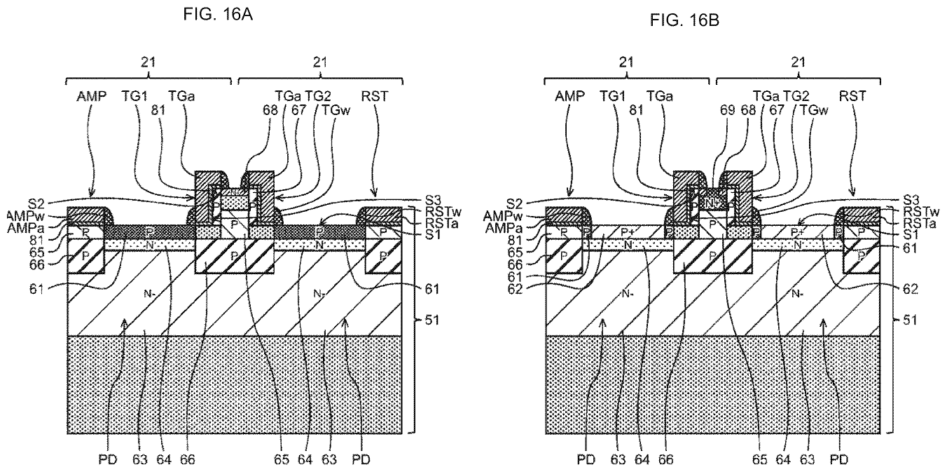

Next, as illustrated in A of FIG. 16, a sidewall of each pixel transistor is formed. That is, the sidewall TGw around the gate electrode TGa of the transfer transistor TG, the sidewall AMPw around the gate electrode AMPa of the amplification transistor AMP, the sidewall RSTw around the gate electrode RSTa of the reset transistor RST, and the sidewall SELw around the gate electrode SELa of the selection transistor SEL are formed (the selection transistor SEL is not illustrated). The step in A of FIG. 16 corresponds to the step in A of FIG. 9 of the first structure example.

Next, as illustrated in B of FIG. 16, ion implantation of P-type impurities and activation annealing treatment are performed on the P-type semiconductor region 61 near the interface of the first surface S1 to form the P-type semiconductor region 62 for shielding the substrate surface. As a result, the P-type semiconductor region 62 becomes higher in impurity concentration than the P-type semiconductor region 61 under the sidewall of each pixel transistor.

Furthermore, ion implantation of N-type impurities and activation annealing treatment are performed on a substrate region surrounded by the gate electrodes TGa of the transfer transistors TG1 to TG4 to form the N-type semiconductor region 69 as the floating diffusion region FD. As a result, the N-type semiconductor region 69 becomes higher in impurity concentration than the N-type semiconductor region 68 of the LDD region. The step in B of FIG. 16 corresponds to the step in B of FIG. 9 of the first structure example.

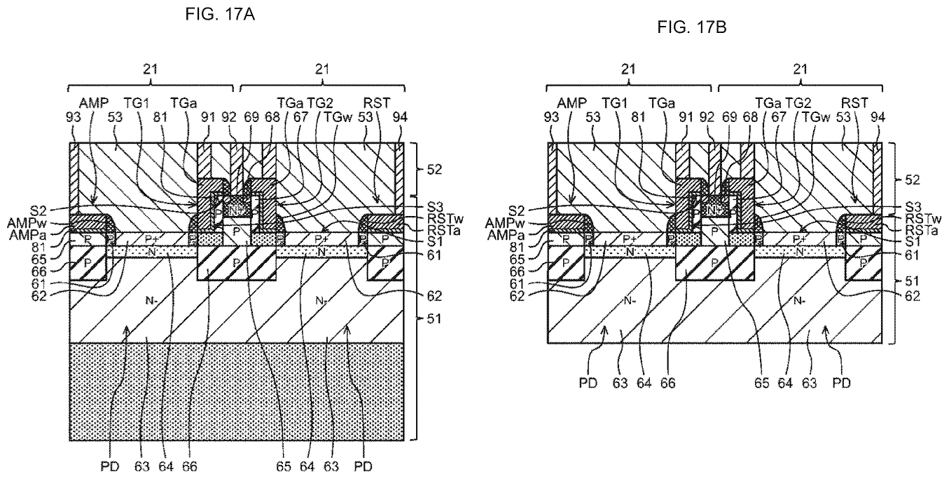

Next, as illustrated in A of FIG. 17, an oxide film or the like is formed on the semiconductor substrate 51 on which the pixel transistors have been formed by, for example, CVD or the like to be a part of the interlayer insulating film 53. Thereafter, a surface of the interlayer insulating film 53 is planarized by CMP, and then a contact hole is formed at a position, corresponding to the contact wirings 91 to 94, of the interlayer insulating film 53 by, for example, RIE. Then, a barrier metal such as TiN/Ti is formed in the formed contact hole, and tungsten (W) is buried by CVD to form the contact wirings 91 to 94. Moreover, wiring (not illustrated) is further formed on the interlayer insulating film 53 using damascene or the like, thereby bringing the multilayer wiring layer 52 to completion. The step in A of FIG. 17 corresponds to the step in A of FIG. 10 of the first structure example.

After the semiconductor substrate 51 on which the multilayer wiring layer 52 and the pixel transistors have been formed is bonded to a logic substrate (not illustrated), as illustrated in B of FIG. 17, the back surface side of the semiconductor substrate 51, in other words, a side of the semiconductor substrate 51 remote from the surface bonded with the logic substrate is thinned until the N-type semiconductor region 63 is exposed. The step in B of FIG. 17 corresponds to the step in B of FIG. 10 of the first structure example.

Steps after the state illustrated in B of FIG. 17 are similar to those of the first structure example described with reference to A and B of FIG. 11, so that description thereof will be omitted. In the steps after the state illustrated in B of FIG. 17, a groove portion 111 is formed in the region to be a pixel trench portion 71, and an insulating film 72, a fixed charge film 73, and an insulating film 74 are buried, in this order, in the formed groove portion 111 to form the pixel trench portion 71.

As described above, the pixel 21 of the second structure example illustrated in FIG. 12 is manufactured. An antireflection film, a color filter layer, a microlens, and the like can be formed on the back surface side serving as the light incident surface of the semiconductor substrate 51, as necessary.

The method is similar to the method for manufacturing the pixel 21 according to the first structure example described above in that the step between the first surface S1 and the second surface S2 may be formed by selective epitaxial growth instead of the step between the first surface S1 and the second surface S2 formed by recess etching of the second surface S2 of the semiconductor substrate 51.

### 7. Third Structure Example of Pixel

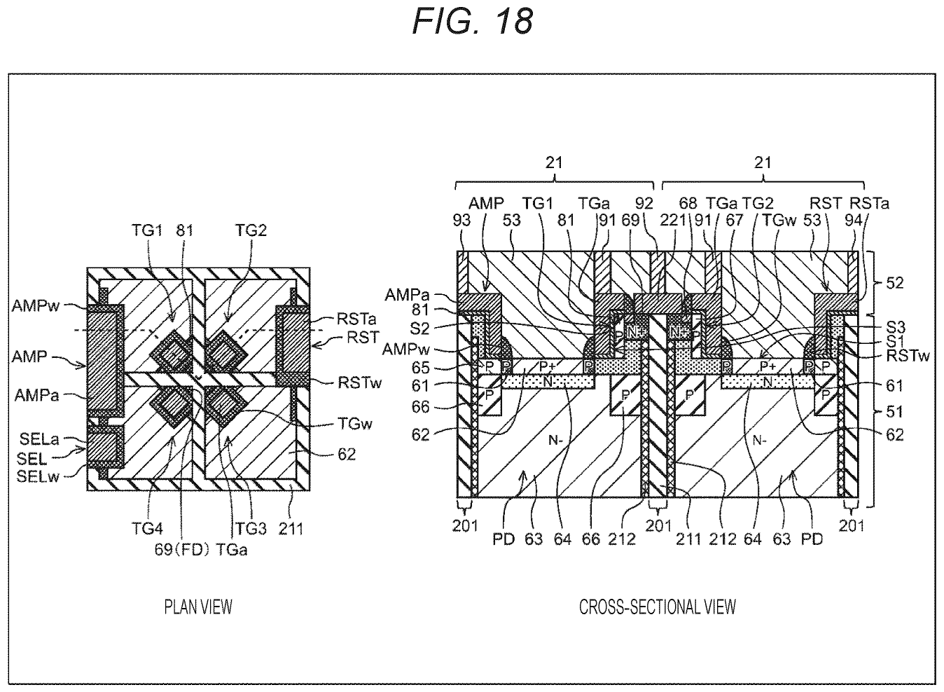

FIG. 18 is a plan view and a cross-sectional view illustrating a third structure example of the pixel 21.

In a manner similar to the first structure example illustrated in FIG. 3, FIG. 18 illustrates a plan view of four pixel regions in a two-by-two arrangement constituting a sharing unit and a cross-sectional view taken along a line segment indicated by a dashed line in the plan view.

In FIG. 18, parts corresponding to those in the first structure example illustrated in FIG. 3 are denoted by the same reference signs, description of those parts will be omitted as appropriate, and description will be given focusing on parts different from those in the first structure example.

In the pixel 21 of the third structure example in FIG. 18, a pixel trench portion 201 is provided instead of the pixel trench portion 71 of the first structure example illustrated in FIG. 3.

The pixel trench portion 71 of the first structure example is formed at the pixel boundary portion to extend from the back surface side (the lower surface in FIG. 18) of the semiconductor substrate 51 to a predetermined depth not reaching the front surface side.

On the other hand, the pixel trench portion 201 of the third structure example extends through from the back surface side to the front surface side of the semiconductor substrate 51 to partition the photoelectric conversion region formed for each pixel into pixel units. An insulating film 211 is buried in the pixel trench portion 201. As the insulating film 211, for example, a silicon oxide (SiO2), a silicon nitride (Si3N4), a silicon oxynitride (SiON), or the like can be used. A P-type semiconductor region 212 is formed on an outer side (side surface) of the pixel trench portion 201.

Since the pixel trench portion 201 extends through from the back surface side to the front surface side of the semiconductor substrate 51, the N-type semiconductor region 69 as the floating diffusion region FD formed at the center portion of the four pixel regions in a two-by-two arrangement is also partitioned into pixel units. Therefore, a doped polysilicon layer 221 is formed on the N-type semiconductor region 69, and the N-type semiconductor region 69 partitioned for each pixel is electrically connected by the doped polysilicon layer 221 as a connection electrode. A contact wiring 92 is connected to the doped polysilicon layer 221.

A configuration of the third structure example in FIG. 18 other than the points described above is similar to that of the first structure example in FIG. 3.

Also in the third structure example, since the four transfer transistors TG1 to TG4 each include a vertical transistor having a vertical gate electrode structure in a manner similar to the first structure example, it is possible to realize a transfer transistor small in gate capacitance and excellent in transfer characteristics. Even in a case where the pixel 21 is reduced in size, the transfer characteristics can be enhanced, and the readout speed can be increased even if the number of pixels of the pixel array unit 11 increases.

### 8. Method for Manufacturing Pixel According to Third Structure Example

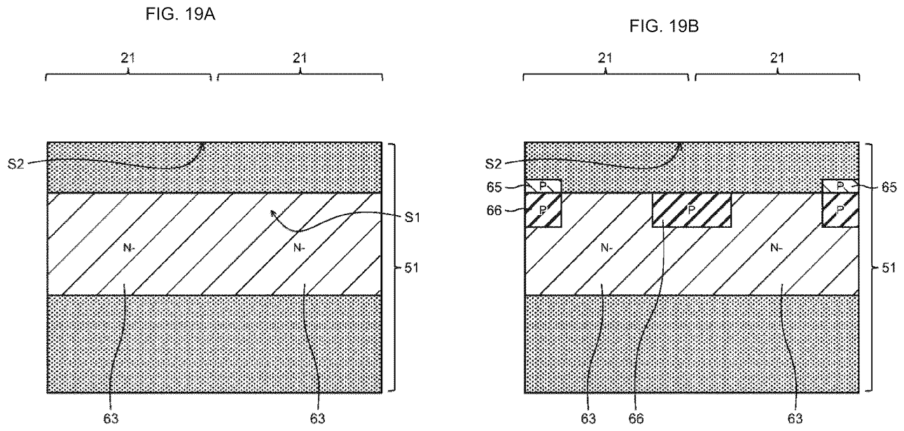

Next, a method for manufacturing the pixel 21 according to the third structure example will be described with reference to FIGS. 19 to 25.

First, as illustrated in A of FIG. 19, the N-type semiconductor region 63 is formed at a predetermined depth of the semiconductor substrate 51. The plane orientation of the front surface of the semiconductor substrate 51 is, for example, a (100) plane, in a manner similar to the above-described examples. The step in A of FIG. 19 corresponds to the step in B of FIG. 5 of the first structure example.

As illustrated in B of FIG. 19, P-type impurities such as boron (B) are ion-implanted into the pixel boundary portion of the pixels 21 that partitions the pixel region into rectangular regions in a matrix, and activation annealing treatment is further performed to form the P-type semiconductor regions 65 and 66. The P-type semiconductor region 65 is formed in a substrate region on the interface between the substrate region adjacent to the front surface of the semiconductor substrate 51 and the N-type semiconductor region 63. The P-type semiconductor region 66 is formed in the N-type semiconductor region 63 under the interface between the substrate region adjacent to the front surface of the semiconductor substrate 51 and the N-type semiconductor region 63. The step in B of FIG. 19 corresponds to the step in A of FIG. 6 of the first structure example, but is different from the step in A of FIG. 6 of the first structure example in that the P-type semiconductor region 65 is not formed in the transfer transistor region.

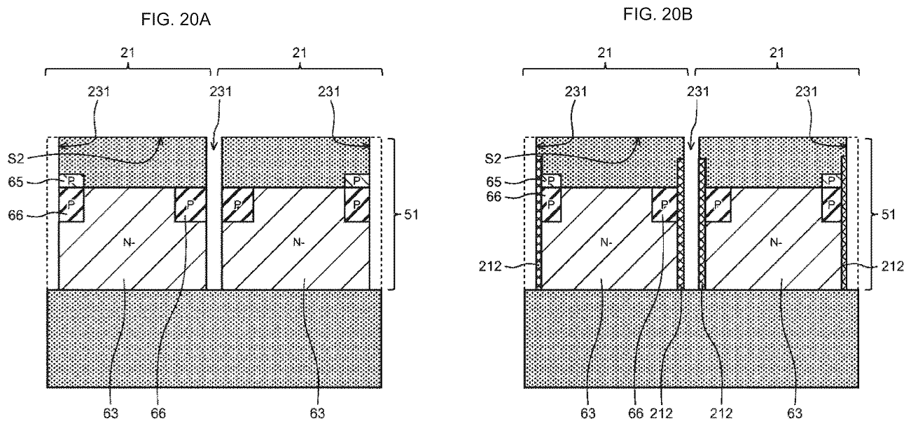

Next, as illustrated in A of FIG. 20, the region to be the pixel trench portion 201 is etched from the front surface side of the semiconductor substrate 51 to form a groove portion 231. The groove portion 231 is formed at least to a depth that penetrates the N-type semiconductor region 63.

Next, as illustrated in B of FIG. 20, the P-type semiconductor region 212 is formed in the N-type semiconductor region 63 and the substrate region near the side wall of the groove portion 231 using, for example, solid phase diffusion. Specifically, doping with boron is made by depositing boron-doped glass in the opened groove portion 231 and performing heat treatment. Note that the P-type semiconductor region 212 may be formed using plasma doping instead of solid phase diffusion.

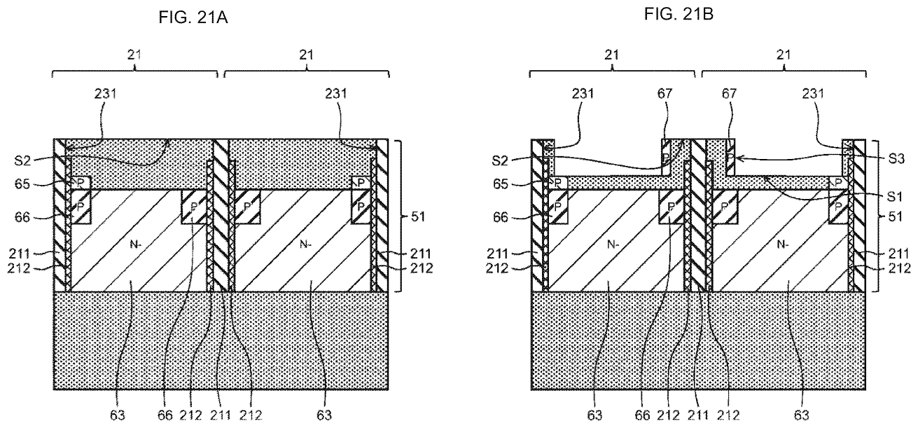

Next, as illustrated in A of FIG. 21, the insulating film 211 is buried in the groove portion 231 using, for example, CVD. As the insulating film 211, for example, a silicon oxide (SiO2), a silicon nitride (Si3N4), a silicon oxynitride (SiON), or the like can be used.

Next, as illustrated in B of FIG. 21, the substrate region on the N-type semiconductor region 63 is partially removed to a predetermined depth by recess etching using, for example, RIE. Specifically, a substrate region of the semiconductor substrate 51 excluding the transfer transistor region and the shared transistor region is subjected to etching to form a recess in the semiconductor substrate 51 for each pixel. As a result, the first surface S1 obtained by cutting into the semiconductor substrate 51 by recess etching, the second surface S2 not etched, and the side surface S3 connecting the first surface S1 and the second surface S2 are formed on the front surface of the semiconductor substrate 51.

Moreover, as illustrated in B of FIG. 21, P-type impurities are ion-implanted into a portion to be the channel region of the transfer transistor TG, and activation annealing treatment is performed on the portion to form the P-type semiconductor region 67. The step in B of FIG. 21 corresponds to the step in B of FIG. 6 of the first structure example.

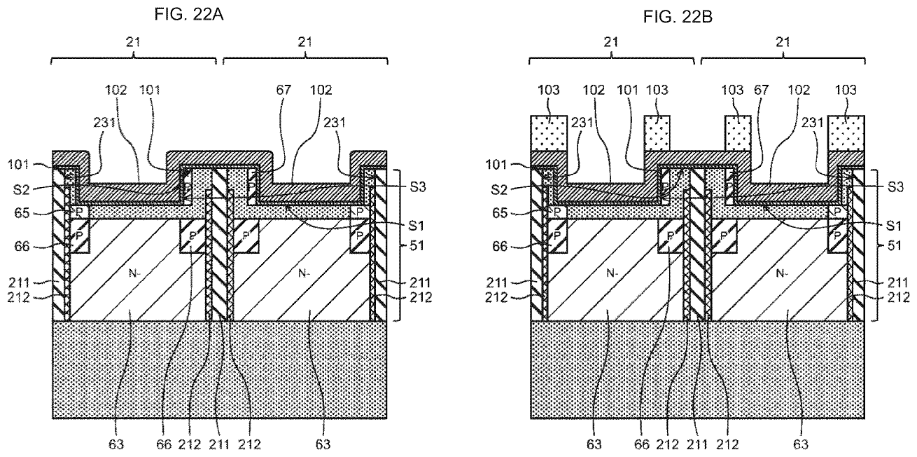

Next, as illustrated in A of FIG. 22, the surface of the semiconductor substrate 51 is subjected to oxidation treatment using, for example, ISSG to form the oxide film 101 to be used as the gate insulating film 81. Subsequently, the polysilicon layer 102 to be used as the gate electrode TGa and the like is formed on an upper surface of the oxide film 101 using, for example, LPCVD. The oxide film 101 has, for example, a thickness of about 6 nm, and the polysilicon layer 102 has, for example, a thickness of about 100 nm. Thereafter, for example, impurities such as phosphorus are introduced into the polysilicon layer 102 by ion implantation with about 3×10¹⁵ cm⁻² and an acceleration voltage of 5 KeV, and activation annealing treatment based on RTA is performed at 1000° C. for about 10 seconds to activate the impurities introduced into the polysilicon layer 102. As in A of FIG. 22, corners of the polysilicon layer 102 are rounded according to irregularities of the semiconductor substrate 51, but are illustrated as right-angled corners in the other drawings for the sake of simplicity. The step in A of FIG. 22 corresponds to the step in A of FIG. 7 of the first structure example.

Next, as illustrated in B of FIG. 22, the resist 103 is formed on an upper surface of the polysilicon layer 102, and is patterned by lithography according to the positions of the gate electrodes formed in the transfer transistor region and the shared transistor region. The step in B of FIG. 22 corresponds to the step in B of FIG. 7 of the first structure example.

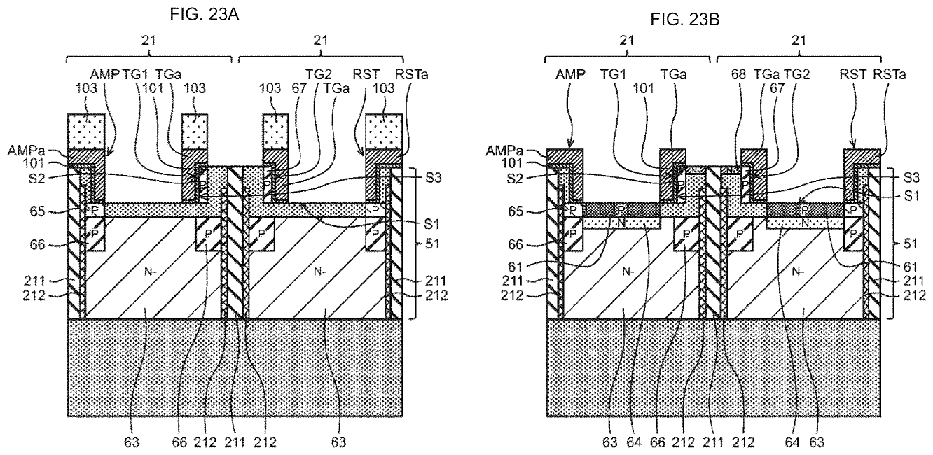

Next, as illustrated in A of FIG. 23, etching such as RIE is performed according to the patterned resist 103, so that the polysilicon layer 102 and the oxide film 101 other than the transistor regions are removed. Thereafter, the patterned resist 103 is removed. As a result, the gate electrode TGa and the gate insulating film 81 of the transfer transistor TG are formed in the transfer transistor region, and the gate electrode AMPa and the gate insulating film 81 of the amplification transistor AMP, the gate electrode RSTa and the gate insulating film 81 of the reset transistor RST, and the like are formed in the shared transistor region. Their respective gate electrodes of the transfer transistor region and the shared transistor region have a vertical gate electrode structure. The step in A of FIG. 23 corresponds to the step in A of FIG. 8 of the first structure example.

Next, as illustrated in B of FIG. 23, ion implantation of P-type impurities and N-type impurities and activation annealing treatment are sequentially performed on a portion near the interface of the first surface S1 of the semiconductor substrate 51 from which the polysilicon layer 102 and the oxide film 101 have been removed to form the P-type semiconductor region 61 and the N-type semiconductor region 64. The P-type semiconductor region 61 is formed in a layer near the interface of the first surface S1, and the N-type semiconductor region 64 is formed in a layer under the P-type semiconductor region 61.

Furthermore, ion implantation of N-type impurities and activation annealing treatment are performed on a substrate region surrounded by the gate electrodes TGa of the transfer transistors TG1 to TG4 to form the N-type semiconductor region 68 to be the LDD region. The step in B of FIG. 23 corresponds to the step in B of FIG. 8 of the first structure example.

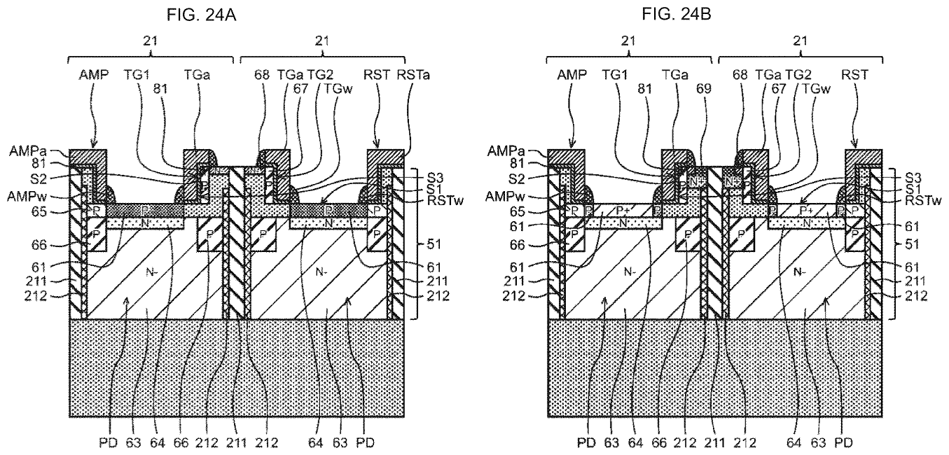

Next, as illustrated in A of FIG. 24, a sidewall of each pixel transistor is formed. That is, the sidewall TGw around the gate electrode TGa of the transfer transistor TG, the sidewall AMPw around the gate electrode AMPa of the amplification transistor AMP, the sidewall RSTw around the gate electrode RSTa of the reset transistor RST, and the sidewall SELw around the gate electrode SELa of the selection transistor SEL are formed (the selection transistor SEL is not illustrated). The step in A of FIG. 24 corresponds to the step in A of FIG. 9 of the first structure example.

Next, as illustrated in B of FIG. 24, ion implantation of P-type impurities and activation annealing treatment are performed on the P-type semiconductor region 61 near the interface of the first surface S1 to form the P-type semiconductor region 62 for shielding the substrate surface. As a result, the P-type semiconductor region 62 becomes higher in impurity concentration than the P-type semiconductor region 61 under the sidewall of each pixel transistor.

Furthermore, ion implantation of N-type impurities and activation annealing treatment are performed on a substrate region surrounded by the gate electrodes TGa of the transfer transistors TG1 to TG4 to form the N-type semiconductor region 69 as the floating diffusion region FD. As a result, the N-type semiconductor region 69 becomes higher in impurity concentration than the N-type semiconductor region 68 of the LDD region. The step in B of FIG. 24 corresponds to the step in B of FIG. 9 of the first structure example.

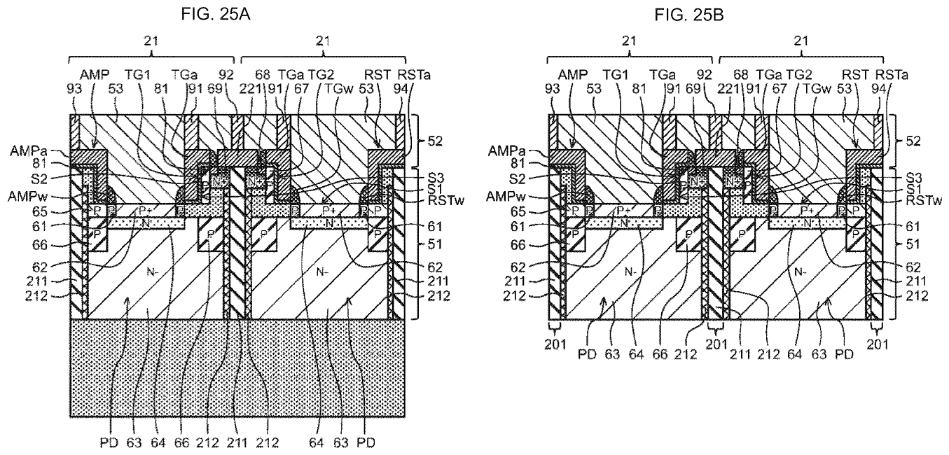

Next, as illustrated in A of FIG. 25, the doped polysilicon layer 221 is formed on the upper surface of the N-type semiconductor region 69 as the floating diffusion region FD, and then the interlayer insulating film 53 is formed. After the surface of the interlayer insulating film 53 is planarized by CMP, contact holes are formed at positions corresponding to the contact wirings 91 to 94 of the interlayer insulating film 53, and a barrier metal such as TiN/Ti and tungsten (W) are buried to form the contact wirings 91 to 94. Moreover, wiring (not illustrated) is further formed on the interlayer insulating film 53 using damascene or the like, thereby bringing the multilayer wiring layer 52 to completion. The step in A of FIG. 25 corresponds to the step in A of FIG. 10 of the first structure example.

After the semiconductor substrate 51 on which the multilayer wiring layer 52 and the pixel transistors have been formed is bonded to a logic substrate (not illustrated), as illustrated in B of FIG. 25, the back surface side of the semiconductor substrate 51, in other words, a side of the semiconductor substrate 51 remote from the surface bonded with the logic substrate is thinned until the N-type semiconductor region 63 is exposed. The step in B of FIG. 25 corresponds to the step in B of FIG. 10 of the first structure example.

As described above, the pixel 21 of the third structure example illustrated in FIG. 18 is manufactured. An antireflection film, a color filter layer, a microlens, and the like can be formed on the back surface side serving as the light incident surface of the semiconductor substrate 51, as necessary.

The method is similar to the method for manufacturing the pixel 21 according to the first structure example described above in that the step between the first surface S1 and the second surface S2 may be formed by selective epitaxial growth instead of the step between the first surface S1 and the second surface S2 formed by recess etching of the second surface S2 of the semiconductor substrate 51.

### 9. Modification of Transfer Transistor

Next, a modification of the transfer transistor TG that can be replaced with the transfer transistors TG of the first structure example to the third structure example described above will be described.

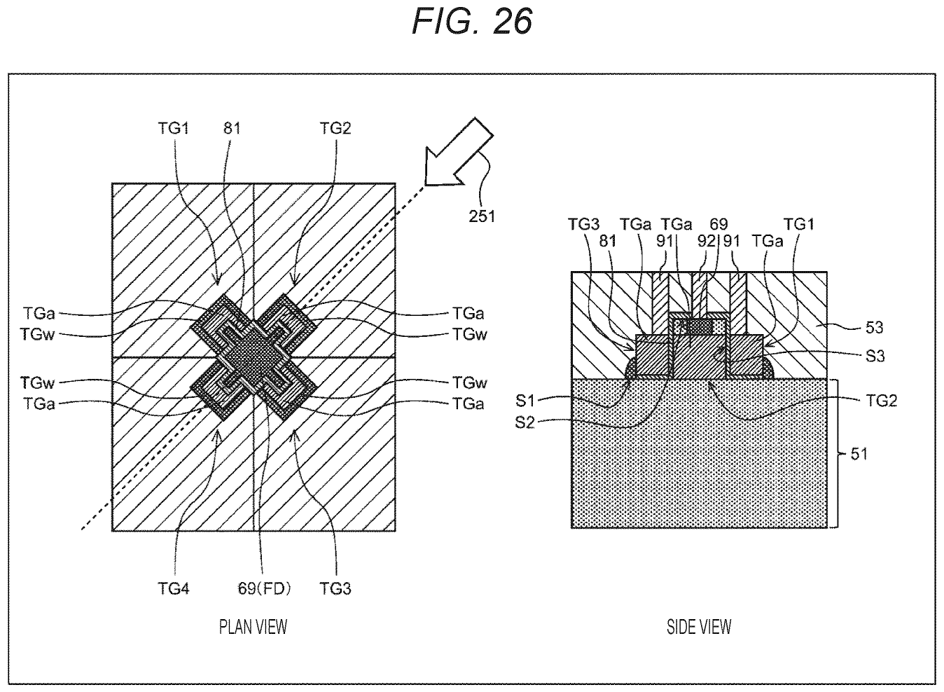

FIG. 26 is a plan view and a side view of the modification of the transfer transistor TG.

The plan view on the left side of FIG. 26 is a plan view of the transfer transistor TG and the floating diffusion region FD, and the side view on the right side is a side view of the transfer transistor TG as viewed from a direction indicated by an arrow 251 in the plan view.

Parts of the transfer transistor TG in FIG. 26 corresponding to those in the first structure example illustrated in FIG. 3 are denoted by the same reference signs, description of those parts will be omitted as appropriate, and description will be given focusing on parts different from those in the first structure example.

In the transfer transistors TG of the first structure example to the third structure example described above, the gate electrode TGa is formed on the second surface S2 and the side surface S3, and has a flipped L-shaped cross-sectional shape obtained by flipping an L-shape vertically.

On the other hand, as illustrated in the side view, the gate electrode TGa of the transfer transistor TG in FIG. 26 is formed only on the side surface S3 and is not formed on the second surface S2. As illustrated in the plan view, the gate electrode TGa has a planar shape in which a surface in contact with the floating diffusion region FD (N-type semiconductor region 69) with the gate insulating film 81 interposed therebetween is recessed.

On the other hand, the N-type semiconductor region 69 that is the floating diffusion region FD has a protruding portion (fin portion) on a surface in contact with the gate electrode TGa of each of the transfer transistors TG1 to TG4 with the gate insulating film 81 interposed therebetween, and the protruding portion of the N-type semiconductor region 69 enters the corresponding recess of the gate electrode TGa.

As described above, the gate electrode TGa has a planar shape with recesses that each surround the corresponding protruding portion of the N-type semiconductor region 69 as the floating diffusion region FD with three surfaces, thereby enhancing the transfer characteristics of the transfer transistor TG.

Note that, in the example in FIG. 26, an example of a structure in which the gate electrode TGa of the transfer transistor TG has a shape recessed in the middle, and the N-type semiconductor region 69 as the floating diffusion region FD has a shape protruding in the middle like a fin has been described; however, the recessed shape of the gate electrode TGa and the protruding shape of the N-type semiconductor region 69 may be reversed. That is, the gate electrode TGa of the transfer transistor TG may have a shape protruding in the middle like a fin, and the N-type semiconductor region 69 as the floating diffusion region FD may have a shape recessed in the middle.

### 10. Application Example to Phase Difference Detection Pixel

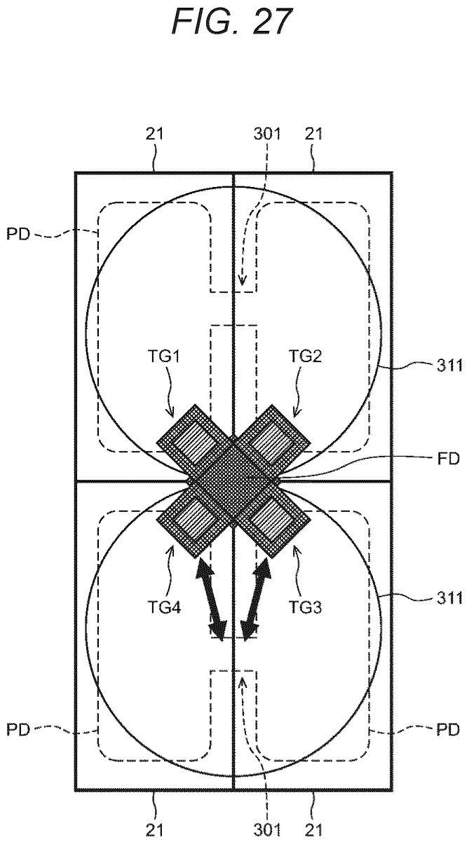

FIG. 27 is a plan view of a pixel configuration example where the transfer transistor TG is applied to a phase difference detection pixel.

There is known a phase difference detection pixel in which one on-chip lens is arranged on a plurality of adjacent pixels, and each pixel sharing one on-chip lens can output a phase difference signal. Configuration examples of the phase difference detection pixel include a configuration in which one on-chip lens is arranged on two pixels adjacent to each other in the row direction, a configuration in which one on-chip lens is arranged on four pixels in a two-by-two arrangement, and the like.

In the example in FIG. 27, one on-chip lens 311 is arranged on two pixels 21 adjacent to each other in the row direction. Each pixel 21 has a rectangular pixel shape so as to make a pixel region of the two pixels on which one on-chip lens 311 is arranged square.

The pixels 21 that are four pixels in a two-by-two arrangement share the floating diffusion region FD, and the floating diffusion region FD is arranged at the center portion of the four pixel regions constituting the sharing unit. The transfer transistor TG of each pixel 21 is arranged near the floating diffusion region FD.

In such a pixel configuration example, in a case where the vertical drive unit 12 of the solid-state imaging device 1 outputs signals of the two pixels sharing one on-chip lens 311 on a pixel-by-pixel basis, for example, an R pixel signal corresponding to light received by the pixel 21 (R pixel) on the right side of one on-chip lens 311 and an L pixel signal corresponding to light received by the pixel 21 (L pixel) on the left side are different in phase, and therefore can be used as a phase difference signal.

On the other hand, in a case where the signals are used as signals for a captured image without detecting the phase difference, the transfer transistors TG of the two pixels sharing one on-chip lens 311 are simultaneously turned on.

An overflow path 301 is formed between the photodiodes PD of the two pixels sharing one on-chip lens 311. The overflow path 301 separates the L pixel and the R pixel with a predetermined potential barrier (separation potential). Signal charges of the L pixel and the R pixel are separately accumulated in the respective photodiodes PD until the amount of signal charges reaches a height of the potential barrier of the overflow path 301. When the amount of signal charges exceeds the height of the potential barrier of the overflow path 301, the signal charges flow from one of the photodiodes PD of the two pixels to the other through the overflow path 301.

It is possible to make, by applying the above-described vertical gate electrode structure to the transfer transistor TG of each pixel 21 capable of detecting such a phase difference, a plane area of the gate electrode small, so that it is possible to make a distance between the transfer transistor TG and the overflow path 301 long enough as compared to the planar transfer transistor. It is therefore possible to achieve a structure in which the separation potential of the overflow path 301, which is an important characteristic of the phase difference detection pixel, is less susceptible to variations in the potential of the transfer transistor TG.

### 11. Usage example of image sensor

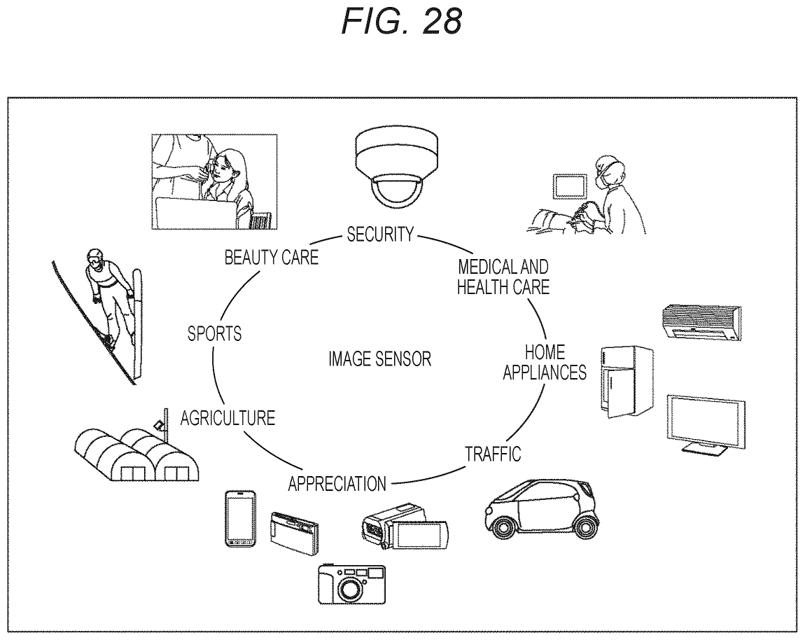

FIG. 28 is a diagram illustrating a usage example of an image sensor using the above-described solid-state imaging device 1.

The above-described solid-state imaging device 1 can be used as an image sensor in various cases of sensing light such as visible light, infrared light, ultraviolet light, and X-rays as described below, for example.
A device that captures an image to be used for viewing, such as a digital camera and a portable device with a camera function
A device for traffic purpose such as an in-vehicle sensor that captures images of the front, rear, surroundings, interior and the like of an automobile, a surveillance camera for monitoring traveling vehicles and roads, and a ranging sensor that measures a distance between vehicles and the like for safe driving such as automatic braking and recognition of a driver's condition
A device for home appliance such as a television, a refrigerator, and an air conditioner that images a user's gesture and performs device operation according to the gesture
A device for medical and health care use such as an endoscope and a device that performs angiography by receiving infrared light
A device for security use such as a security monitoring camera and an individual authentication camera
A device used for beauty care, such as a skin measuring instrument for imaging skin, and a microscope for imaging the scalp
A device used for sports, such as an action camera or a wearable camera for sports applications or the like
A device used for agriculture, such as a camera for monitoring a condition of a field or crop

### 12. Application Example to Electronic Apparatus

The technology of the present disclosure is applicable to not only the solid-state imaging device but also other devices. That is to say, the technology of the present disclosure may be applied to any electronic apparatuses in which the solid-state imaging device is used in an image capturing unit (photoelectric conversion unit) such as an imaging device such as a digital still camera and a video camera, a portable terminal device having an imaging function, and a copying machine in which the solid-state imaging device is used in the image reading unit. The solid-state imaging device may be formed as one chip, or may be in a module form having an imaging function in which an imaging unit and a signal processing unit or an optical system are packaged together.

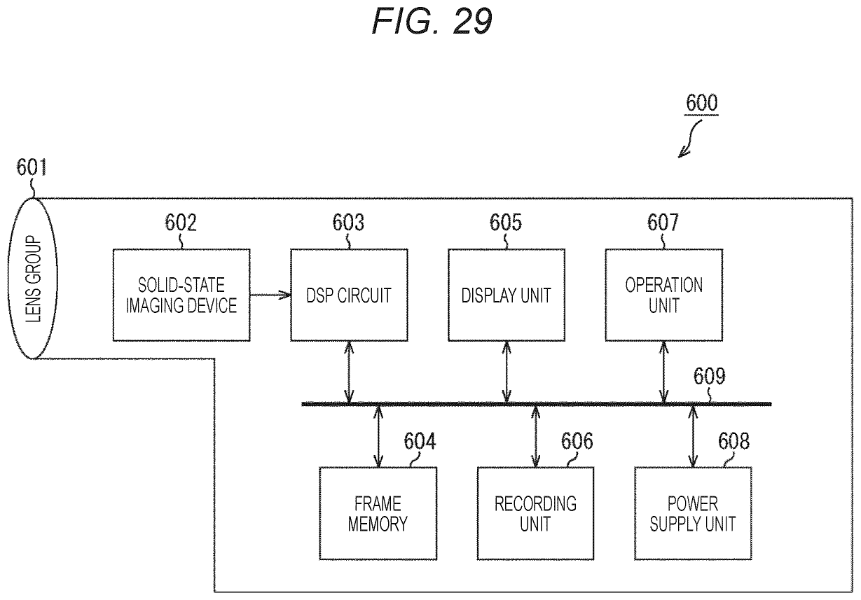

FIG. 29 is a block diagram illustrating a configuration example of an imaging device as an electronic apparatus to which the technology of the present disclosure is applied.

An imaging device 600 in FIG. 29 includes an optical unit 601 including a lens group and the like, a solid-state imaging device (imaging device) 602 in which the configuration of the solid-state imaging device 1 in FIG. 1 is adopted, and a digital signal processor (DSP) circuit 603 that is a camera signal processing circuit. The imaging device 600 further includes a frame memory 604, a display unit 605, a recording unit 606, an operation unit 607, and a power supply unit 608. The DSP circuit 603, the frame memory 604, the display unit 605, the recording unit 606, the operation unit 607, and the power supply unit 608 are connected to one another via a bus line 609.

The optical unit 601 captures incident light (image light) from a subject and forms an image on an imaging surface of the solid-state imaging device 602. The solid-state imaging device 602 converts the light amount of the incident light imaged on the imaging surface by the optical unit 601 into an electrical signal on a pixel-by-pixel basis and outputs the electrical signal as a pixel signal. As the solid-state imaging device 602, the solid-state imaging device 1 in FIG. 1, that is, a solid-state imaging device having a vertical gate electrode structure in which the floating diffusion region FD is formed on the second surface S2 higher than the first surface S1 of the semiconductor substrate 51, and the gate electrode TGa of the transfer transistor TG is formed on the side surface S3 connecting the first surface S1 and the second surface S2, is used.

The display unit 605 includes, for example, a thin display such as a liquid crystal display (LCD) or an organic electro luminescence (EL) display, and displays a moving image or a still image captured by the solid-state imaging device 602. The recording unit 606 records the moving image or the still image captured by the solid-state imaging device 602 on a recording medium such as a hard disk or a semiconductor memory.

The operation unit 607 issues operation commands for various functions of the imaging device 600 under operation by the user. The power supply unit 608 supplies various kinds of power that is the operating power for the DSP circuit 603, the frame memory 604, the display unit 605, the recording unit 606, and the operation unit 607 to these supply targets, as appropriate.

As described above, the use of the solid-state imaging device 1 to which the transfer transistor TG having a vertical gate electrode structure described above is applied as the solid-state imaging device 602 allows an increase in readout speed even if the number of pixels increases. Therefore, even in the imaging device 600 such as a video camera, a digital still camera, or a camera module for a mobile device such as a mobile phone, a high-quality captured image can be acquired at high speed.

In the above-described example, the solid-state imaging device in which the first conductivity type is the P-type, the second conductivity type is the N-type, and electrons are used as signal charges has been described, but the present disclosure can also be applied to a solid-state imaging device in which holes are used as signal charges. That is, the first conductivity type may be the N-type, the second conductivity type may be the P-type, and the conductivity types of the above-described respective semiconductor regions may be reversed.

Furthermore, an example in which the technology of the present disclosure is applied to a solid-state imaging device that outputs an image signal has been described. However, the technology of the present disclosure can be applied not only to a solid-state imaging device but also to any photodetection devices including pixels that receive and photoelectrically convert incident light. For example, the technology can also be applied to a light receiving device (distance measuring sensor) of a distance measuring system that receives infrared light emitted as active light and measures a distance to a subject by a direct ToF method or an indirect ToF method. Furthermore, the technology of the present disclosure is not limited to application to a solid-state imaging device that detects distribution of the amount of incident light of visible light and captures the distribution as an image, and can be applied to any solid-state imaging devices (physical quantity distribution detection devices) such as a solid-state imaging device that captures distribution of the amount of incident infrared rays, X-rays, particles, or the like as an image, a fingerprint detection sensor that detects distribution of other physical quantities such as pressure, capacitance, and the like, and captures the distribution as an image in a broad sense, and the like.

Furthermore, the technology of the present disclosure is applicable not only to a solid-state imaging device but also to any semiconductor devices having other semiconductor integrated circuits.

The embodiment of the present disclosure is not limited to the above-described embodiment, and various modifications may be made without departing from the gist of the technology of the present disclosure.

The effects described herein are merely examples and are not limited, and there may be other effects.

Note that the technology of the present disclosure may have the following configurations.

(1)

A solid-state imaging device including:
a photoelectric conversion region formed in a semiconductor substrate, the semiconductor substrate having a first surface and a second surface with different heights formed adjacent to a wiring layer;
a floating diffusion region formed on an opposite side of the semiconductor substrate from the photoelectric conversion region relative to the first surface and between the first surface and the second surface; and
a transfer transistor that transfers charges generated in the photoelectric conversion region to the floating diffusion region, in which
the transfer transistor has a vertical gate electrode structure in which a gate electrode is formed on a side surface connecting the first surface and the second surface.

(2)

The solid-state imaging device according to the above (1), in which
the gate electrode of the transfer transistor is further formed on the second surface.

(3)

The solid-state imaging device according to the above (1) or (2), in which
the floating diffusion region is shared by a plurality of pixels.

(4)

The solid-state imaging device according to any one of the above (1) to (3), in which
the photoelectric conversion region is formed for each pixel, and
one on-chip lens is arranged for a plurality of pixels, and
each pixel sharing the one on-chip lens is configured to be able to output a phase difference signal.

(5)

The solid-state imaging device according to any one of the above (1) to (4), in which
the gate electrode formed on the side surface has a height of 0.2 μm or more.

(6)

The solid-state imaging device according to any one of the above (1) to (5), in which
an amplification transistor, a reset transistor, and a selection transistor also each include a pixel transistor having the vertical gate electrode structure.

(7)

The solid-state imaging device according to any one of the above (1) to (6), in which
the gate electrode has a recessed planar shape surrounding the floating diffusion region with three surfaces.

(8)

The solid-state imaging device according to any one of the above (1) to (7), further including
a pixel trench portion obtained by cutting into the semiconductor substrate to a predetermined depth from a back surface that is an opposite side of the semiconductor substrate from the first surface and the second surface, the pixel trench portion partitioning the photoelectric conversion region into pixel units.

(9)

The solid-state imaging device according to any one of the above (1) to (7), further including
a pixel trench portion extending through the semiconductor substrate and partitioning the photoelectric conversion region into pixel units.

(10)

The solid-state imaging device according to the above (9), further including
a doped polysilicon layer connecting the floating diffusion region of each pixel partitioned by the pixel trench portion.

(11)

The solid-state imaging device according to any one of the above (1) to (5), in which
an amplification transistor, a reset transistor, and a selection transistor each include a pixel transistor having a planar gate electrode.

(12)

The solid-state imaging device according to any one of the above (1) to (11), in which
a step is formed between the first surface and the second surface by subjecting, to etching, a region of the second surface of the semiconductor substrate other than at least a region where the floating diffusion region is formed.

(13)

The solid-state imaging device according to any one of the above (1) to (11), in which
a step is formed between the first surface and the second surface by subjecting, to selective epitaxial growth, a region of the first surface of the semiconductor substrate including at least a region where the floating diffusion region is formed.

(14)

An electronic apparatus including a solid-state imaging device, the solid-state imaging device including:
a photoelectric conversion region formed in a semiconductor substrate, the semiconductor substrate having a first surface and a second surface with different heights formed adjacent to a wiring layer;
a floating diffusion region formed on an opposite side of the semiconductor substrate from the photoelectric conversion region relative to the first surface and between the first surface and the second surface; and
a transfer transistor that transfers charges generated in the photoelectric conversion region to the floating diffusion region, in which
the transfer transistor has a vertical gate electrode structure in which a gate electrode is formed on a side surface connecting the first surface and the second surface.

### REFERENCE SIGNS LIST

1 Solid-state imaging device
21 Pixel
PD Photodiode
FD Floating diffusion region
TG Transfer transistor
TGa Gate electrode
AMP Amplification transistor
AMPa Gate electrode
RST Reset transistor
RSTa Gate electrode
SEL Selection transistor
SELa Gate electrode
S1 First surface
S2 Second surface
S3 Side surface
52 Multilayer wiring layer
53 Interlayer insulating film
61 P-type semiconductor region
62 P-type semiconductor region
63 N-type semiconductor region
64 N-type semiconductor region
65 P-type semiconductor region
66 P-type semiconductor region
67 P-type semiconductor region
68 N-type semiconductor region
69 N-type semiconductor region
71 Pixel trench portion
72 Insulating film
73 Fixed charge film
74 Insulating film
81 Gate insulating film
201 Pixel trench portion
211 Insulating film
212 P-type semiconductor region
221 Doped polysilicon layer
301 Overflow path
311 On-chip lens
600 Imaging device
602 Solid-state imaging device

1. A solid-state imaging device comprising:
a photoelectric conversion region formed in a semiconductor substrate, the semiconductor substrate having a first surface and a second surface with different heights formed adjacent to a wiring layer;
a floating diffusion region formed on an opposite side of the semiconductor substrate from the photoelectric conversion region relative to the first surface and between the first surface and the second surface; and
a transfer transistor that transfers charges generated in the photoelectric conversion region to the floating diffusion region, wherein
the transfer transistor has a vertical gate electrode structure in which a gate electrode is formed on a side surface connecting the first surface and the second surface.

2. The solid-state imaging device according to claim 1, wherein
the gate electrode of the transfer transistor is further formed on the second surface.

3. The solid-state imaging device according to claim 1, wherein
the floating diffusion region is shared by a plurality of pixels.

4. The solid-state imaging device according to claim 1, wherein
the photoelectric conversion region is formed for each pixel, and
one on-chip lens is arranged for a plurality of pixels, and
each pixel sharing the one on-chip lens is configured to be able to output a phase difference signal.

5. The solid-state imaging device according to claim 1, wherein
the gate electrode formed on the side surface has a height of 0.2 μm or more.

6. The solid-state imaging device according to claim 1, wherein
an amplification transistor, a reset transistor, and a selection transistor also each include a pixel transistor having the vertical gate electrode structure.

7. The solid-state imaging device according to claim 1, wherein
the gate electrode has a recessed planar shape surrounding the floating diffusion region with three surfaces.

8. The solid-state imaging device according to claim 1, further comprising
a pixel trench portion obtained by cutting into the semiconductor substrate to a predetermined depth from a back surface that is an opposite side of the semiconductor substrate from the first surface and the second surface, the pixel trench portion partitioning the photoelectric conversion region into pixel units.

9. The solid-state imaging device according to claim 1, further comprising
a pixel trench portion extending through the semiconductor substrate and partitioning the photoelectric conversion region into pixel units.

10. The solid-state imaging device according to claim 9, further comprising
a doped polysilicon layer connecting the floating diffusion region of each pixel partitioned by the pixel trench portion.

11. The solid-state imaging device according to claim 1, wherein
an amplification transistor, a reset transistor, and a selection transistor each include a pixel transistor having a planar gate electrode.

12. The solid-state imaging device according to claim 1, wherein
a step is formed between the first surface and the second surface by subjecting, to etching, a region of the second surface of the semiconductor substrate other than at least a region where the floating diffusion region is formed.

13. The solid-state imaging device according to claim 1, wherein
a step is formed between the first surface and the second surface by subjecting, to selective epitaxial growth, a region of the first surface of the semiconductor substrate including at least a region where the floating diffusion region is formed.

14. An electronic apparatus comprising
a solid-state imaging device, the solid-state imaging device including:
a photoelectric conversion region formed in a semiconductor substrate, the semiconductor substrate having a first surface and a second surface with different heights formed adjacent to a wiring layer;
a floating diffusion region formed on an opposite side of the semiconductor substrate from the photoelectric conversion region relative to the first surface and between the first surface and the second surface; and
a transfer transistor that transfers charges generated in the photoelectric conversion region to the floating diffusion region, wherein
the transfer transistor has a vertical gate electrode structure in which a gate electrode is formed on a side surface connecting the first surface and the second surface.
